(19) United States
(12) Patent Application Publication
(10) Pub. No.: US 2011/0253197 A1
(43) Pub. Date: Oct. 20, 2011

(54) TUNED SOLAR CONCENTRATORS AND DEVICES AND METHODS USING THEM

(75) Inventors: Jonathan K. Mapel, East Boston, MA (US); Marc Alexander Baldo, Cambridge, MA (US); Carlijn L. Mulder, Boston, MA (US); Carmel Rotschild, Brookline, MA (US); Michael James Currie, Groton, MA (US); Phillip D. Reusswig, Cambridge, MA (US)

(73) Assignee: MASSACHUSETTS INSTITUTE OF TECHNOLOGY, Cambridge, MA (US)

(21) Appl. No.: 13/029,730

(22) Filed: Feb. 17, 2011

Related U.S. Application Data
(60) Provisional application No. 61/305,424, filed on Feb. 17, 2010.
(60) Provisional application No. 61/328,076, filed on Apr. 26, 2010.
(60) Provisional application No. 61/356,915, filed on Jun. 21, 2010.

(51) Int. Cl. H01L 31/052; G02B 5/08; H01L 31/0232

(52) U.S. Cl. 136/247; 136/257; 359/884

(57) ABSTRACT

Solar concentrators are disclosed that improve the efficiency of PV cells and systems using them. The solar concentrators may be designed such that they include one or more tuned chromophores that emit light substantially in a single direction to a PV cell. Various materials and components of the solar concentrators are also described.

### CROSS REFERENCE TO RELATED APPLICATIONS

This application claims the benefit under 35 U.S.C. §119(e) of co-pending U.S. Provisional Application Nos. 61/305,424 entitled “TUNED SOLAR CONCENTRATORS AND DEVICES AND METHODS USING THEM” filed on Feb. 17, 2010; 61/328,076 entitled “TUNED SOLAR CONCENTRATORS AND DEVICES AND METHODS USING THEM” filed on Apr. 26, 2010; and 61/356,915 entitled “TUNED SOLAR CONCENTRATORS AND DEVICES AND METHODS USING THEM” filed on Jun. 21, 2010, which are all herein incorporated by reference in their entireties.

### FEDERALLY SPONSORED RESEARCH

This invention was made with government support under NSF (NIRT) Grant No. 6897058 and DOE Grant No. 6916465. The government has certain rights in this invention.

### FIELD OF THE TECHNOLOGY

Certain embodiments of the technology disclosed herein relate generally to solar concentrators and devices and methods using them. More particularly, certain examples disclosed herein are directed to solar concentrators that may include one or more emitters that are tuned.

### BACKGROUND

Solar cells may be used to convert solar energy into electrical energy. Many solar cells are inefficient, however, with a small fraction of the incident solar energy actually being converted into a usable current. Also, the high cost of solar cells limits their use as a renewable energy source.

In addition, light collection losses in solar cells are the largest source in photovoltaic power conversion efficiencies. These collection losses are typically more extreme in the ultraviolet and blue regions of the solar spectrum. Due to a large fraction of sunlight being absorbed in the top micron of the semiconductor material, extensive laboratory research has been undertaken to optimize the front surface of photovoltaic devices. However, to date, such methods may not be amenable to inclusion in a commercial production process. Thus, a need remains for further processes and more efficient photovoltaic cells.

### SUMMARY

In accordance with a first aspect, a solar concentrator is disclosed. In some examples, the solar concentrator comprises a substrate and at least first and second closely spaced chromophores disposed on or in the substrate in a manner to receive at least some optical radiation, the first chromophore effective to absorb at least one wavelength of at least some of the optical radiation and further effective to transfer at least some energy by Förster energy transfer to the second chromophore, the second chromophore effective to emit at least some of the transferred energy at a wavelength that is red-shifted from the wavelength absorbed by the first chromophore, in which second chromophore is tuned to provide light emission in substantially one direction.

In certain embodiments, the substrate is a glass comprising a refractive index of at least 1.7. In other embodiments, the second chromophore is tuned by trapping the second chromophore in a matrix or by disposing the second chromophore in a viscous medium. In some examples, the concentrator may further comprise an effective amount of a red-shifting agent to shift an emission wavelength range of the second chromophore to a higher wavelength range. In certain examples, the second chromophore is tuned using an electric field applied to the solar concentrator. In other examples, the second chromophore is selected from the group consisting of an organometallic compound, a porphyrin compound, a chromophore assembly and a chromophore complex. In some embodiments, the concentrator may further comprise at least one wavelength selective mirror disposed on the substrate, the wavelength selective mirror configured to transmit incident light in a first wavelength range and to reflect incident light in a second wavelength range. In some examples, the first and second chromophores are both tuned by trapping them in a matrix, wherein at least one of the first and second chromophores is covalently bound to the matrix. In certain embodiments, the concentrator may further comprise a first photovoltaic cell optically coupled to the solar concentrator. In other embodiments, the concentrator may further comprise a second photovoltaic cell optically coupled to the solar concentrator, wherein the efficiency of the first and second photovoltaic cells are different.

In another aspect, a solar concentrator comprising a substrate and a plurality of chromophores disposed on or in the substrate in a manner to receive at least some optical radiation, the plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores, in which the terminal chromophore is tuned to provide light emission in substantially one direction is disclosed.

In certain examples, the substrate is a glass comprising a refractive index of at least 1.7. In other examples, the terminal chromophore is tuned by trapping the terminal chromophore in a matrix or by disposing the terminal chromophore in a viscous medium. In some embodiments, the concentrator may further comprise an effective amount of a red-shifting agent to shift an emission wavelength range of the second chromophore to a higher wavelength range. In some examples, the second chromophore is tuned using an electric field applied to the solar concentrator. In other examples, the second chromophore is selected from the group consisting of an organometallic compound, a porphyrin compound, a chromophore assembly and a chromophore complex. In some embodiments, the concentrator may further comprise at least one wavelength selective mirror disposed on the substrate, the wavelength selective mirror configured to transmit incident light in a first wavelength range and to reflect incident light in a second wavelength range. In certain examples, two or more of the chromophores are tuned by trapping them in a matrix, wherein at least one of the tuned chromophores is covalently bound to the matrix. In other examples, the concentrator may further comprise a first photovoltaic cell optically coupled to the solar concentrator. In certain examples, the concentrator may further comprise a second photovoltaic cell optically coupled to the solar concentrator, wherein the efficiency of the first and second photovoltaic cells are different.

In an additional aspect, a solar concentrator comprising a substrate and a film disposed on the substrate in a manner to receive at least some optical radiation is provided. In certain examples, the film comprises at least a first chromophore and a second chromophore, the first chromophore effective to absorb at least one wavelength of at least some of the optical radiation and further effective to transfer at least some energy by Förster energy transfer to the second chromophore, the second chromophore effective to emit at least some of the transferred energy at a wavelength that is red-shifted from the wavelength absorbed by the first chromophore, in which the second chromophore is tuned to provide light emission in substantially one direction.

In certain embodiments, the substrate is a glass comprising a refractive index of at least 1.7. In other embodiments, the second chromophore is tuned by trapping the second chromophore in a matrix or by disposing the second chromophore in a viscous medium. In some embodiments, the concentrator further comprises an effective amount of a red-shifting agent to shift an emission wavelength range of the second chromophore to a higher wavelength range. In other examples, the second chromophore is tuned using an electric field applied to the solar concentrator. In some examples, the second chromophore is selected from the group consisting of an organometallic compound, a porphyrin compound, a chromophore assembly and a chromophore complex. In additional examples, the concentrator further comprises at least one wavelength selective mirror disposed on the substrate, the wavelength selective mirror configured to transmit incident light in a first wavelength range and to reflect incident light in a second wavelength range. In some embodiments, the first and second chromophores are both tuned by trapping them in a polar matrix, wherein at least one of the first and second chromophores is covalently bound to the matrix. In other embodiments, the concentrator further comprises a first photovoltaic cell optically coupled to the solar concentrator. In other examples, the concentrator further comprises a second photovoltaic cell optically coupled to the solar concentrator, wherein the efficiency of the first and second photovoltaic cells are different.

In another aspect, a solar concentrator comprising a substrate and a film disposed on the substrate in a manner to receive at least some optical radiation, the film comprising a plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores, in which the terminal chromophore is tuned to provide emission in substantially one direction is provided.

In certain examples, the substrate is a glass comprising a refractive index of at least 1.7. In other examples, the terminal chromophore is tuned by trapping the terminal chromophore in a matrix or by disposing the terminal chromophore in a viscous medium. In some examples, the concentrator further comprises an effective amount of a red-shifting agent to shift an emission wavelength range of the second chromophore to a higher wavelength range. In certain embodiments, the terminal chromophore is tuned using an electric field applied to the solar concentrator In some embodiments, the terminal chromophore is selected from the group consisting of an organometallic compound, a porphyrin compound, a chromophore assembly and a chromophore complex. In other embodiments, the concentrator further comprises at least one wavelength selective mirror disposed on the substrate, the wavelength selective mirror configured to transmit incident light in a first wavelength range and to reflect incident light in a second wavelength range. In additional examples, two or more of the chromophores are tuned by trapping them in a matrix, wherein at least one of the tuned chromophores is covalently bound to the matrix. In other examples, the concentrator further comprises a first photovoltaic cell optically coupled to the solar concentrator. In additional examples, the concentrator further comprises a second photovoltaic cell optically coupled to the solar concentrator, wherein the efficiency of the first and second photovoltaic cells are different.

In an additional aspect, a solar concentrator comprising a substrate and a film disposed on the substrate in a manner to receive at least some optical radiation, the film comprising at least a first chromophore and a second chromophore, the first chromophore effective to absorb at least some of the optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present in the film at a concentration at least ten times greater than the concentration of the second chromophore in the film, in which the second chromophore is tuned to provide emission in substantially one direction is disclosed.

In certain embodiments, the substrate is a glass comprising a refractive index of at least 1.7. In other embodiments, the second chromophore is tuned by trapping the second chromophore in a matrix or by disposing the second chromophore in a viscous medium. In additional embodiments, the concentrator further comprises an effective amount of a red-shifting agent to shift an emission wavelength range of the second chromophore to a higher wavelength range. In certain examples, the second chromophore is tuned using an electric field applied to the solar concentrator. In other examples, the second chromophore is selected from the group consisting of an organometallic compound, a porphyrin compound, a chromophore assembly and a chromophore complex. In some examples, the concentrator further comprises at least one wavelength selective mirror disposed on the substrate, the wavelength selective mirror configured to transmit incident light in a first wavelength range and to reflect incident light in a second wavelength range. In other examples, the first and second chromophores are both tuned by trapping them in a matrix, wherein at least one of the first and second chromophores is covalently bound to the matrix. In some embodiments, the concentrator further comprises a first photovoltaic cell optically coupled to the solar concentrator. In certain embodiments, the concentrator further comprises a second photovoltaic cell optically coupled to the solar concentrator, wherein the efficiency of the first and second photovoltaic cells are different.

In another aspect, a solar concentrator comprising a substrate and a composition disposed on or in the substrate in a manner to absorb at least some optical radiation, the composition comprising a material effective to absorb at least some of the optical radiation within a first wavelength range and to emit the absorbed optical radiation by phosphorescence within a second wavelength range that is red-shifted from the first wavelength range, in which the first and second wavelength ranges do not substantially overlap in wavelength, in which the material is tuned to provide emission in substantially one direction is provided.

In certain examples, the substrate is a glass comprising a refractive index of at least 1.7. In other examples, the material is tuned by trapping the material in a matrix or by disposing the material in a viscous medium. In some examples, the concentrator may comprise an effective amount of a red-shifting agent to shift an emission wavelength range of the material to a higher wavelength range. In certain embodiments, the material is tuned using an electric field applied to the solar concentrator. In other embodiments, the material is selected from the group consisting of an organometallic compound, a porphyrin compound, a chromophore assembly and a chromophore complex. In additional embodiments, the concentrator comprises at least one wavelength selective mirror disposed on the substrate, the wavelength selective mirror configured to transmit incident light in a first wavelength range and to reflect incident light in a second wavelength range. In other examples, the material is tuned by trapping it in a matrix and wherein the material is covalently bound to the matrix. In some examples, the concentrator further comprises a first photovoltaic cell optically coupled to the solar concentrator. In additional examples, the concentrator further comprises a second photovoltaic cell optically coupled to the solar concentrator, wherein the efficiency of the first and second photovoltaic cells are different.

In another aspect, a solar concentrator comprising a substrate and a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength ranges that is red-shifted from the first wavelength range, the composition further comprising an effective amount of a red-shifting agent to shift the second wavelength range to a higher wavelength range such that the first and second wavelength ranges do not substantially overlap in wavelength, in which at least one of the material and the red-shifting agent is tuned to provide emission in substantially one direction is provided.

In certain embodiments, the substrate is a glass comprising a refractive index of at least 1.7. In other embodiments, the first and second wavelength ranges overlap by less than 20 nm. In some examples, the red-shifting agent is effective to shift the second wavelength range by at least 100 nm. In additional examples, the material is selected from the group consisting of an organometallic compound, a porphyrin compound, a chromophore assembly and a chromophore complex. In other examples, the material is tuned by trapping it in a matrix or by disposing the material in a viscous medium. In some examples, the concentrator further comprises at least one wavelength selective mirror disposed on the substrate, the wavelength selective mirror configured to transmit incident light in a first wavelength range and to reflect incident light in a second wavelength range. In certain examples, the material is tuned using an electric field. In other examples, the concentrator further comprises a first photovoltaic cell optically coupled to the solar concentrator. In some examples, the concentrator further comprises a second photovoltaic cell optically coupled to the solar concentrator, wherein the efficiency of the first and second photovoltaic cells are different.

In an additional aspect, a solar concentrator comprising a substrate and a composition disposed on or in the substrate in a manner to absorb at least some optical radiation, the composition comprising at least one tuned chromophore assembly effective to provide emission in substantially one direction is disclosed.

In certain examples, the substrate is a glass comprising a refractive index of at least 1.7. In some examples, the tuned chromophore assembly is selected from the group consisting of a chromophore complex and a chromophore aggregate, such as those described in commonly owned U.S. Provisional Patent Application No. 61/146,550 filed on Jan. 22, 2009, the entire disclosure of which is hereby incorporated herein by reference for all purposes. In other examples, the composition further comprises a red-shifting agent. In certain examples, the composition further comprises a plurality of absorbing chromophores and one terminal chromophore. In additional examples, the tuned chromophore assembly is tuned using an electric field, by trapping it in a matrix or by disposing it in a viscous medium. In certain embodiments, the concentrator further comprises at least one wavelength selective mirror disposed on the substrate, the wavelength selective mirror configured to transmit incident light in a first wavelength range and to reflect incident light in a second wavelength range. In other embodiments, the concentrator further comprises a matrix to which the chromophore assembly is covalently bound. In some examples, the concentrator further comprises a first photovoltaic cell optically coupled to the solar concentrator. In other examples, the concentrator further comprises a second photovoltaic cell optically coupled to the solar concentrator, wherein the efficiency of the first and second photovoltaic cells are different.

In another aspect, a solar concentrator comprising a substrate and a composition disposed on or in the substrate in a manner to absorb at least some optical radiation, the composition comprising at least one chromophore assembly effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength, in which the chromophore assembly is tuned to provide emission in substantially one direction is disclosed.

In certain embodiments, the substrate is a glass comprising a refractive index of at least 1.7. In some embodiments, the tuned chromophore assembly is selected from the group consisting of a chromophore complex and a chromophore aggregate, such as those described in commonly owned U.S. Provisional Patent Application No. 61/146,550 filed on Jan. 22, 2009, the entire disclosure of which is hereby incorporated herein by reference for all purposes. In certain examples, the composition further comprises a red-shifting agent. In other examples, the composition further comprises a plurality of absorbing chromophores and one terminal chromophore. In some examples, the tuned chromophore assembly is tuned using an electric field, by trapping it in a matrix or by disposing it in a viscous medium. In additional examples, the concentrator further comprises at least one wavelength selective mirror disposed on the substrate, the wavelength selective mirror configured to transmit incident light in a first wavelength range and to reflect incident light in a second wavelength range. In other examples, the concentrator further comprises a matrix to which the chromophore assembly is covalently bound. In some examples, the concentrator further comprises a first photovoltaic cell optically coupled to the solar concentrator. In other examples, the concentrator further comprises a second photovoltaic cell optically coupled to the solar concentrator, wherein the efficiency of the first and second photovoltaic cells are different.

In another aspect, a solar concentrator comprising a substrate and a composition disposed on or in the substrate in a manner to absorb at least some optical radiation, the composition comprising at least one tuned chromophore assembly effective to absorb at least some of the optical radiation within a first wavelength range and to emit the absorbed optical radiation by phosphorescence in substantially one direction and within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength is described.

In certain embodiments, the substrate is a glass comprising a refractive index of at least 1.7. In other embodiments, the tuned chromophore assembly is selected from the group consisting of a chromophore complex and a chromophore aggregate, such as those described in commonly owned U.S. Provisional Patent Application No. 61/146,550 filed on Jan. 22, 2009, the entire disclosure of which is hereby incorporated herein by reference for all purposes. In some embodiments, the red-shifting agent is effective to shift the second wavelength range by at least 100 nm. In other embodiments, the composition further comprises a plurality of absorbing chromophores and one terminal chromophore. In additional embodiments, the tuned chromophore assembly is tuned using an electric field, by trapping it in a matrix or by disposing it in a viscous medium. In some examples, the concentrator further comprises at least one wavelength selective mirror disposed on the substrate, the wavelength selective mirror configured to transmit incident light in a first wavelength range and to reflect incident light in a second wavelength range. In certain examples, the concentrator further comprises a matrix in which the chromophore assembly is covalently bound. In additional examples, the concentrator further comprises a first photovoltaic cell optically coupled to the solar concentrator. In some examples, the concentrator further comprises a second photovoltaic cell optically coupled to the solar concentrator, wherein the efficiency of the first and second photovoltaic cells are different.

In an additional aspect, a solar concentrator comprising a substrate and a composition disposed on or in the substrate in a manner to absorb at least some optical radiation, the composition comprising at least one tuned chromophore assembly effective to absorb at least some of the optical radiation within a first wavelength range and to emit the absorbed optical radiation by phosphorescence in substantially one direction and within a second wavelength range that is red-shifted from the first wavelength range, the composition further comprising an effective amount of a red-shifting agent complexed to the organometallic compound to shift the second wavelength range to a higher wavelength range such that the first and second wavelength ranges do not substantially overlap in wavelength is provided.

In certain embodiments, the substrate is a glass comprising a refractive index of at least 1.7. In other embodiments, the tuned chromophore assembly is selected from the group consisting of a chromophore complex and a chromophore aggregate, such as those described in commonly owned U.S. Provisional Patent Application No. 61/146,550 filed on Jan. 22, 2009, the entire disclosure of which is hereby incorporated herein by reference for all purposes. In some embodiments, the red-shifting agent is effective to shift the second wavelength range by at least 100 nm In other embodiments, the composition further comprises a plurality of absorbing chromophores and one terminal chromophore. In some examples, the tuned chromophore assembly is tuned using an electric field, by trapping it in a matrix or by disposing it in a viscous medium. In additional examples, the concentrator further comprises at least one wavelength selective mirror disposed on the substrate, the wavelength selective mirror configured to transmit incident light in a first wavelength range and to reflect incident light in a second wavelength range. In additional examples, the concentrator further comprises matrix to which the chromophore assembly is covalently bound. In other examples, the concentrator further comprises a first photovoltaic cell optically coupled to the solar concentrator. In additional examples, the concentrator further comprises a second photovoltaic cell optically coupled to the solar concentrator, wherein the efficiency of the first and second photovoltaic cells are different.

In another aspect, a solar concentrator comprising a substrate and a first chromophore and a second chromophore disposed on or in the substrate, wherein the first chromophore is oriented at an angle to increase absorption of light incident on the substrate and the second chromophore is tuned to provide light emission in substantially the plane of the concentrator, and wherein the first chromophore transfers energy to the second chromophore which emits light is disclosed. In some examples, the first chromophore may be oriented with respect to the substrate, the angle of incident light, the orientation of the second chromophore or combinations thereof including all of the them.

In certain embodiments, the concentrator further comprises a first photovoltaic cell optically coupled to the solar concentrator. In other examples, the concentrator further comprises a second photovoltaic cell optically coupled to the solar concentrator, wherein the efficiency of the first and second photovoltaic cells are different. In certain examples, the second chromophore is tuned using an electric field, by trapping it in a matrix or by disposing it in a viscous medium.

In another aspect, a tandem device comprising any one of the solar concentrators described herein coupled to a thin film photovoltaic cell, wherein the solar concentrator and the thin film photovoltaic cell are each selected to have different bandgaps is disclosed.

In an additional aspect, a device comprising any one or more of the solar concentrators described herein coupled to a portable electronic device is provided. In certain examples, the portable electronic device is selected from the group consisting of a digital audio player, a mobile phone, a personal digital assistant, a portable computer, an image sensor, a camera, and a mobile environmental sensor.

In certain embodiments, the tuned chromophore assembly and/or luminescence processes disclosed herein may be applied to increasing the blue wavelength response of solar cells in device configurations where little to no solar concentration occurs. By absorbing short wavelength photons and emitting longer wavelength photons in a spectral region where the quantum efficiency of light to electrical conversion is higher (e.g., the visible or red region of the solar spectrum), overall power conversion efficiency of non-concentrated solar modules may be desirably increased.

Like LSCs, tuned chromophore photo-luminescence from chromophores directly applied to a PV may exit a glass substrate if emitted in a direction that is not totally internally reflected by the top substrate face. The tuned chromophores disclosed herein that increase confinement efficiency may also serve to reduce light emission out of the front substrate face. Thus, they are directly applicable to being utilized as luminescent coatings applied directly to solar modules with physical structures where little to no solar concentration occurs. Tuned chromophore photo-luminescence from chromophores directly applied to a PV device do not include a low refractive index medium between the substrates that support the tuned photo-luminescent chromophores and the PV device.

In certain embodiments, the devices disclosed herein may be used to increase efficiency of any associated PV device.

Additional features, aspects, examples and embodiments are possible and will be recognized by the person of ordinary skill in the art, given the benefit of this disclosure.

### BRIEF DESCRIPTION OF THE FIGURES

Certain illustrative features, aspects, examples and embodiments are described below with reference to the figures in which:

FIG. 1A is an illustration of one embodiment of a solar concentrator, in accordance with certain examples;

FIG. 1B is schematic used to define the dipole axis angle and shows maximum emission occurring perpendicular to the dipole axis, in accordance with certain examples;

FIG. 1C is a graph showing the dependence of confinement efficiency on the dipole axis, in accordance with certain examples;

FIG. 1D is a schematic used to define the dipole axis angle, in accordance with certain examples;

FIG. 1E is a graph showing an increase in efficiency by controlling the emission direction, in accordance with certain examples;

FIG. 1F is an illustration of a diffusing plate and solar concentrator, in accordance with certain examples;

FIG. 1G is a graph of optical quantum efficiency as a function of the angle of incidence of the optical radiation (vertical axis) and the orientation of the chromophore (horizontal axis) for s Monte Carlo simulation, in accordance with certain examples;

FIG. 1H is a plot of the optical quantum efficiency (vertical axis) as a function of the orientation of the chromophore (referred to as molecular orientation), in accordance with certain examples;

FIG. 1J is a plot of the optical quantum efficiency (vertical axis) as a function of the angle of incidence of the light (horizontal axis) relative to the plane of a diffusing plate for several orientations of a chromophore, in accordance with certain examples;

FIGS. 2A and 2B show the absorption and emission spectra of two chromophores, in accordance with certain examples;

FIGS. 3A and 3B are schematics showing thin films disposed on a substrate, in accordance with certain examples;

FIG. 4 shows absorption and emission spectra for a chromophore, in accordance with certain examples;

FIG. 5 shows an absorption spectrum, a fluorescence emission spectrum and a phosphorescence emission spectrum, in accordance with certain examples;

FIG. 6 illustrate red-shifting of an emission spectrum, in accordance with certain examples;

FIG. 7 is a schematic of a substrate comprising wavelength selective mirrors disposed on opposite surfaces, in accordance with certain examples;

FIG. 8 is a schematic of a device that include a PV cell embedded in a waveguide, in accordance with certain examples;

FIG. 9 is graph showing the absorption and emission spectra for a chromophore doped with DCTJB, in accordance with certain examples;

FIG. 10 is a graph showing the efficiency of a composition of various chromophores, in accordance with certain examples;

FIG. 11 is a graph showing an increase in Förster energy transfer by doping a chromophore with another material, in accordance with certain examples;

FIG. 12 is a schematic of an embodiment of a tandem solar concentrator, in accordance with certain examples;

FIG. 13 is a graph showing predicted performance of the solar concentrator of FIG. 12, in accordance with certain examples;

FIG. 14 is a schematic showing a solar concentrator with a dessicant layer, in accordance with certain examples;

FIG. 15 is a schematic of another embodiment of a tandem solar concentrator, in accordance with certain examples;

FIG. 16 is a schematic of a packaged solar concentrator, in accordance with certain examples;

FIG. 17 is another schematic of a packaged solar concentrator, in accordance with certain examples;

FIG. 18A is a graph showing the self-absorption ratio in a DCJTB-based solar concentrator is S=80 (dotted lines); a larger self-absorption ratio of S=220 is obtained in a rubrene-based concentrator (solid lines), because the amount of DCJTB is reduced by a factor of three; its absorption is replaced by rubrene, which then transfers energy to DCJTB (see FIG. 18C); the inset of FIG. 18A shows the DCJTB chemical structure;

FIG. 18B is a graph showing phosphorescence emission (FIG. 18D) to reduce self-absorption; the self-absorption ratio in a Pt(TPBP)-based concentrator is S=500; the inset of FIG. 18B shows the Pt(TPBP) chemical structure;

FIG. 18C is a diagram showing energy transfer; near field dipole-dipole coupling can efficiently transfer energy between host and guest molecules; the guest molecule concentration can be less than 1%, significantly reducing self-absorption;

FIG. 18D is a diagram showing phosphorescence emission; spin orbit coupling in a phosphor increases the PL efficiency of the triplet state and the rate of intersystem crossing from singlet to triplet manifolds; the exchange splitting between singlet and triplet states is typically about 0.7 eV, significantly reducing self-absorption;

FIG. 19A shows the optical quantum efficiency (OQE) spectra of the DCJTB, rubrene and Pt(TPBP)-based single waveguide concentrators;

FIG. 19B shows the results from a tandem configuration where light is incident first on the rubrene-based OSC (blue); this filters the incident light incident on the second, mirror-backed, Pt(TPBP)-based concentrator (green). The composite OQE is shown in red;

FIGS. 20A and 20B shows graphs of concentrator efficiency and flux gain as a function of geometric gain; in FIG. 20A, with increasing G, photons must take a longer path to the edge-attached PV, increasing the probability of re-absorption; in FIG. 20B flux gain compares the electrical power output from the solar cell when attached to the concentrator relative to direct solar illumination; the flux gain increases with G, but reaches a maximum when the benefit of additional G is cancelled by self-absorption losses; near field energy transfer and phosphorescence substantially improve the flux gain relative to the DCJTB-based OSC;

FIG. 21 shows an example of a tandem device, in accordance with certain examples.

FIG. 22A shows an example of a device structure where tuned chromophores are directly applied to the front glass face of a thin film photovoltaic module;

FIG. 22B shows an example of a device structure where tuned chromophores are directly applied to the solar cell inside the photovoltaic module;

FIG. 23A shows a schematic representation of the side-view of the integrating sphere measurement set-up to determine trapping efficiency of the LSCs;

FIG. 23B shows a schematic representation of the top-view of the set-up used to test the angular dependence of the absorption of the LSCs;

FIG. 23C illustrates the distance, d, between the excitation spot and the solar cell of the LSC;

FIG. 24A shows the measured Optical Quantum Efficiency (OQE) of the facial emission, edge emission and the total emission of the isotropic LSCs;

FIG. 24B shows the measured Optical Quantum Efficiency (OQE) of the facial emission, edge emission and the total emission of the vertically aligned LSCs;

FIG. 24C illustrates the measured trapping efficiency of the isotropically aligned LSCs and the vertically aligned, homeotropic LSCs;

FIG. 25A shows the power emitted from the edge of an LSC as a function of the incoming angle of the excitation beam for a isotropic LSC and a vertically aligned LSC;

FIG. 25B illustrates the effect of an external diffuser on the edge output power of an isotropic and homeotropic LSC;

FIG. 26 illustrates the external quantum efficiency (EQE) versus geometric gain for vertically aligned LSCs and isotropic dipoles;

FIG. 27 shows the polarized absorption and photoluminescence of the linearly polarized LSCs used in Example 2;

FIG. 28A shows a schematic representation of the OQE integrating sphere measurement set-up used in Example 2;

FIG. 28B shows the OQE for a linearly polarized LSC based on Coumarin 6 dye molecules and a sample co-doped with Coumarin 6 and DCM;

FIG. 29A illustrates a simulation of determining the performance of linearly polarized LSCs based on Coumarin 6 dye molecules as a function of geometric gain; and

FIG. 29B shows the external quantum efficiency versus geometric gain, G, of the LP-LSCs.

It will be recognized by the person of ordinary skill in the art, given the benefit of this disclosure, that the dimensions of certain elements in the figures may have been enlarged, distorted or otherwise shown in a non-conventional manner to provide a more user-friendly description of the technology. In particular, the relative dimensions and thicknesses of the different components in the light emitting devices are not intended to be limited by those shown in the figures.

### DETAILED DESCRIPTION

Certain embodiments of the solar concentrators and devices using them that are disclosed herein provide significant advantages over existing devices including higher efficiencies, fewer components, and improved materials and improved optical properties. These and other advantages will be recognized by the person of ordinary skill in the art, given the benefit of this disclosure. Certain examples of the solar concentrators disclosed herein may be used with low cost solar cells that comprise amorphous or polycrystalline thin films.

Certain materials or components are described herein as being disposed on or in another material or component. The term dispose is intended to be interchangeable with the term deposit and includes, but is not limited to, evaporation, co-evaporation, coating, painting, spraying, brushing, vapor deposition, casting, covalent association, non-covalent association, coordination or otherwise attachment, for at least some time, to a surface. Illustrative methods of disposing a selected component of the solar concentrators disclosed herein are described in more detail below.

In certain examples, the devices and methods disclosed herein are operative to absorb and/or transfer at least some energy. The phrase “at least some” is used herein in certain instances to indicate that not necessarily all of the energy incident on the substrate is absorbed, not necessarily all of the energy is transferred, or not necessarily the energy that is transferred is all emitted as light. Instead, a portion or fraction of the energy may be lost as heat or other non-radiative processes in the solar concentrators disclosed herein.

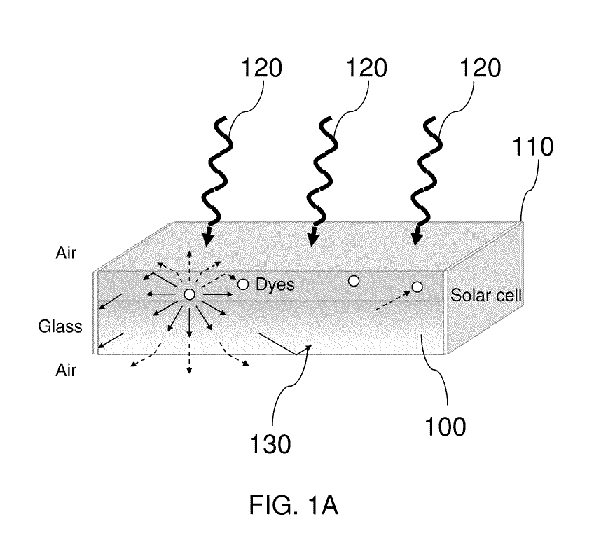

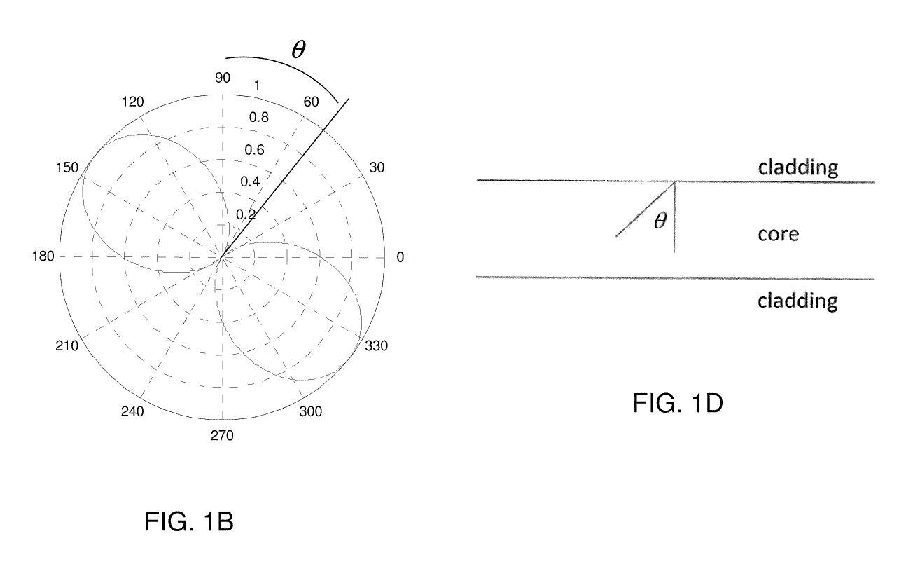

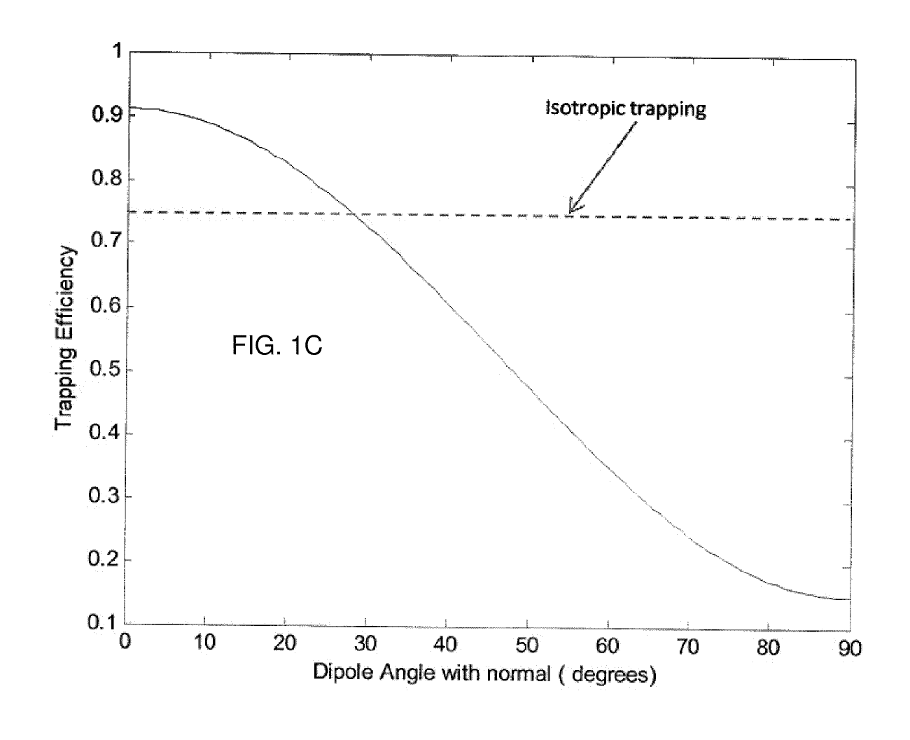

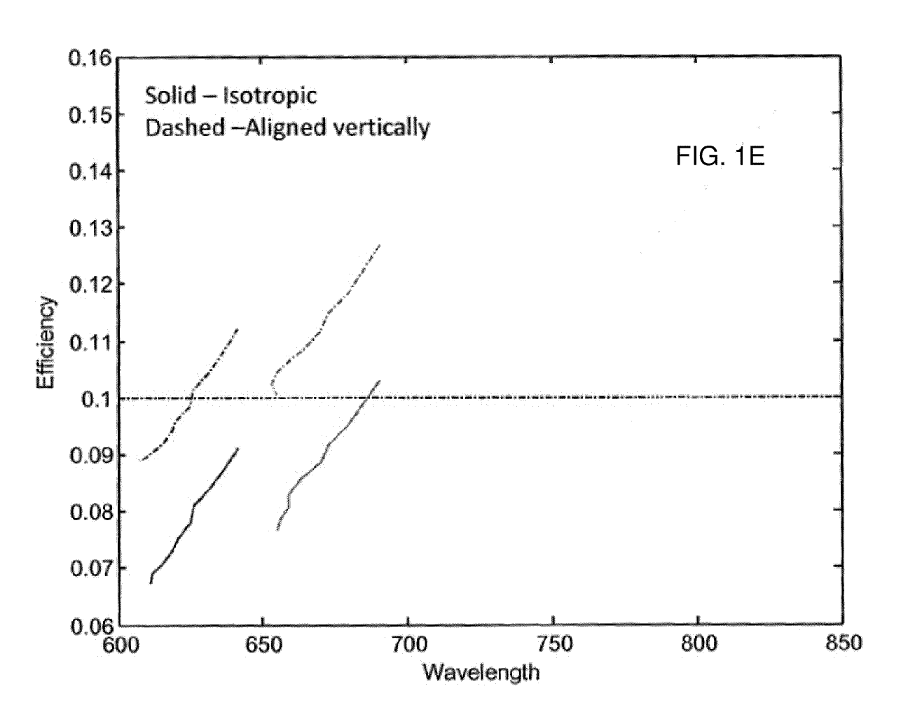

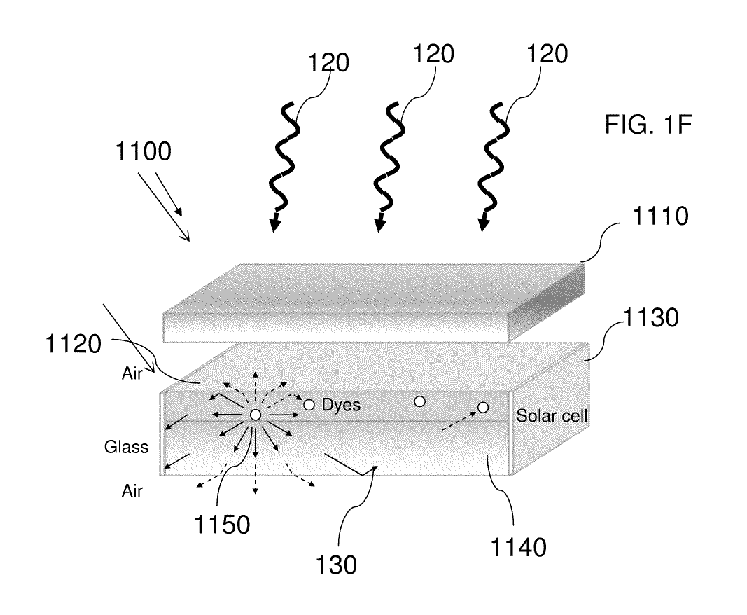

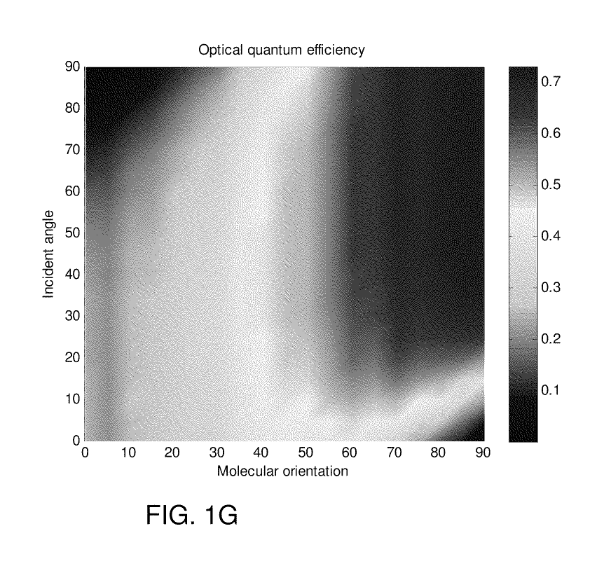

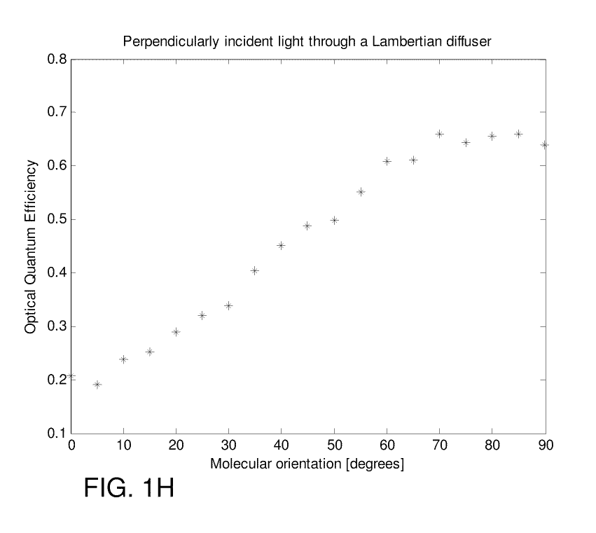

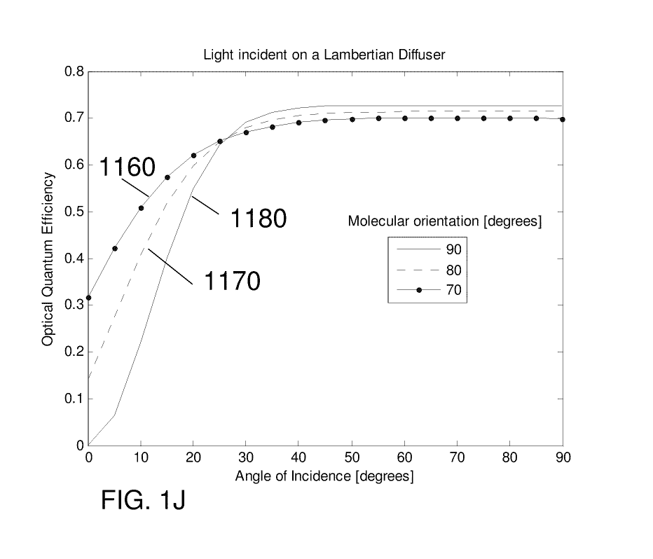

In accordance with certain examples, a luminescent solar concentrator (LSC) separates the photovoltaic functions of light collection and charge separation. For example, light may be gathered by an inexpensive collector that comprises a light absorbing material. The collected light may be focused onto a smaller area of a photovoltaic (PV) cell. The ratio of the area of the collector to the area of the PV cell is known as the geometric concentration factor, G. One attraction of the light concentrator approach is that the complexity of a large area solar cell is replaced by a simple optical collector. PV cells are still used, but large G values of a light concentrator coupled to a PV cell can reduce the PV cost, potentially lowering the overall cost per watt of generated power. An illustrative schematic of a luminescent solar concentrator (LSC) is shown in FIG. 1A. The LSC comprises a substrate 100 that includes one or more light absorbing materials disposed on or in the substrate 100. The substrate 100 is optically coupled to at least one solar cell (also referred to as PV cell) at the edge 110 of the substrate 100. Solar radiation 120 is incident on the substrate 100 where it is absorbed by the light absorbing material(s) in the substrate 100. Energy may be re-radiated (see arrows 130) within the substrate 100, and the re-radiated energy may be guided toward the edge 110 for collection by the PV cells. One advantage of using LSC's over PV concentration systems, e.g., mirrors, lenses, dishes and the like, is that very high concentration factors may be achieved without cooling or mechanical tracking.

In certain embodiments, one or more of the chromophores can be a material that is selected from the group consisting of rare earth phosphors, organometallic complexes, porphyrins, perylene and its derivatives, organic laser dyes, FL-612 from Luminophor JSC, substituted pyrans (such as dicyanomethylene), coumarins (such as Coumarin 30), rhodamines (such as Rhodamine B), oxazine, Exciton LDS series dyes, Nile Blue, Nile Red, DODCI, Epolight 5548, BASF Lumogen dyes (for instance: 083, 170, 240, 285, 305, 570, 650, 765, 788, and 850), other substituted dyes of this type, other oligorylenes, and dyes such as DTTC1, Steryl 6, Steryl 7, pyradines, indocyanine green, styryls (Lambdachrome series), dioxazines, naphthalimides, thiazines, stilbenes, IR132, IR144, IR140, Dayglo Sky Blue (D-286), Columbia Blue (D-298), and organometallic complexes of rare earth metals (such as europium, neodymium, and uranium, such as, for example, those described in C. Adachi, M. A. Baldo, S. R. Forrest, Journal of Applied Physics 87, 8049 (2000); K. Kuriki, Y. Koike, Y. Okamoto, Chemical Reviews 102, 2347 (2002); H. S. Wang, et al, Thin Solid Films 479, 216 (2005); Y. X. Ye, et al, Acta Physica Sinica 55, 6424 (2006).

In accordance with certain examples, the solar concentrators disclosed herein may include a substrate that is operative to trap and/or guide light. The terms substrate and waveguide may be interchanged for the purposes of this disclosure. Such trapped light may be directed to or otherwise coupled to a PV cell such that the light may be converted into a current by the PV cell. The substrate need not be in direct sunlight but instead, may be used to receive direct, indirect and diffuse solar radiation. In some examples as discussed below, the substrate may be selected such that one or more chromophores may be disposed in or on the substrate or the substrate may be impregnated with the chromophore. The chromophore may be any substance that can absorb and/or emit light of a desired or selected wavelength. Any material that can receive a chromophore may be used in the substrates of the solar concentrators described herein.

In accordance with certain examples, the substrate may include a material whose refractive index is greater than 1.7. Illustrative materials for use in the substrates of the solar concentrators disclosed herein include, but are not limited to, polymethylmethyacrylate (PMMA), glass, lead-doped glass, lead-doped plastics, aluminum oxide, polycarbonate, halide-chalcogenide glasses, titania-doped glass, titania-doped plastics, zirconia-doped glass, zirconia-doped plastics, alkaline metal oxide-doped glass, alkaline metal oxide-doped plastics, barium oxide-doped glass, barium-doped plastics, zinc oxide-doped glass, and zinc oxide-doped plastics. In certain examples, the dimensions of the substrate may vary depending on the desired efficiency, overall size of the concentrator and the like. In particular, the substrate may be thick enough such that a sufficient amount of light may be trapped, e.g., 70-80% or more of the quanta of radiation (i.e., 7-80% of the incident photons). In certain examples, the thickness of the substrate may vary from about 1 mm to about 4 mm, e.g., about 1.5 mm to about 3 mm. The overall length and width of the substrate may vary depending on its intended use, and in certain examples, the substrate may be about 10 cm to about 300 cm wide by about 10 cm to about 300 cm long. The exact shape of the substrate may also vary depending on its intended use environment. In some examples, the substrate may be planar or generally planar, whereas in other examples, the substrate may be non-planar. In certain examples, opposite surfaces of the substrate may be substantially parallel, whereas in other examples opposite surfaces may be diverging or converging. For example, the top and bottom surfaces may each be sloped such that the width of the substrate at one end is less than the width of the substrate at an opposite end.

In accordance with certain examples, the solar concentrators disclosed herein may be produced using a high refractive index material. The term “high refractive index” refers to a material having a refractive index of at least 1.7. By increasing the refractive index of the substrate, the light trapping efficiency of the solar concentrator may be increased. Illustrative high refractive index materials suitable for use in the solar concentrators disclosed herein include, but are not limited to, high index glasses such as lead-doped glass, aluminum oxide, halide-chalcogenide glasses, titania-doped glass, zirconia-doped glass, alkaline metal oxide-doped glass, barium oxide-doped glass, zinc oxide-doped glass, and other materials such as, for example, lead-doped plastics, barium-doped plastics, alkaline metal oxide-doped plastics, titania-doped plastics, zirconia-doped plastics, and zinc oxide-doped plastics. In some examples any material whose light trapping efficiency is at least 80% of the quanta of radiation or more may be used as a high refractive index substrate.

In accordance with certain examples, in a typical LSC not all of the emitted photons will be confined in the substrate. For a simple system that include three layers, the trapping efficiency η_{Trap} of the photons in a waveguide may be expressed as

$${η}_{Trap} = \sqrt{1 - \frac{{η}_{cladding}^{2}}{{η}_{core}^{2}}}$$

where η_{cladding} and η_{core} are the refractive indices of the cladding and core, respectively. For a simple air-clad glass waveguide, with core and cladding refractive indices of 1.5 and 1, respectively, about 75% of the re-emitted photons will be trapped. Certain embodiments disclosed herein are configured to increase the efficiency of the solar concentrators by including one or more chromophores whose emission properties, e.g., emission direction, intensity, etc., can be tuned or controlled.

In certain embodiments, at least one chromophore used in the LSC's disclosed herein is effective to emit light in a selected direction. A chromophore that is oriented or aligned in a certain direction or plane is referred to herein as a “tuned chromophore.” As described in more detail below, such direction may be controlled using numerous materials and methods including, but not limited to, chromophore orientation, chromophore local environment, chromophore assembly or aggregation, and/or chromophore emission control. These and other ways of controlling the direction of chromophore emission will be readily selected by the person of ordinary skill in the art, given the benefit of this disclosure. In some examples, the tuned chromophore takes the form of individual chromophore molecules, whereas in other examples, the tuned chromophore may be part of chromophore complex or chromophore assembly as described, for example, in commonly owned U.S. Provisional Application No. 61/146, 550 incorporated by reference herein. In some examples, where more than one chromophore is used, the chromophores may be present together but generally do not form a composite. That is, there is no interface between the materials but instead the materials are present in substantially the same local environment. In other examples, where more than one chromophore is present, the chromophores may be used in a composite, laminate or other device that may include an interface that can separate the chromophores. Where an interface is present, certain portions of the device, but not necessarily the entire device, may include the interface.

In examples where a chromophore assembly is used in the devices and methods described herein, the chromophore assembly may be, for example, a chlorin, a phycobilosome, a porphyrin, a cyanine dye and a perylene bisimide dye. In some examples, the chromophore assembly may be an aggregate including, but not limited to, J-aggregates, H-aggregates and the like. Examples of chlorins include, but are not limited to, metallochlorins (for instance, Zn or Mg), bis(metallochlorins), and the aggregated chlorins in chlorosomal antennas of green bacteria such as Chlroroflexus aurantiacus. Illustrative examples of porphyrins include, but are not limited to, meso-tetrakis(p-sulfonatophenyl)porphyrin, tetraphenylporphinesulfonate, tetracarboxyphenyl-porphine, tetra(N-methyltetrapryidyl)porphine, uroprophyrin I, metallouroporphyrins, urohemin, picket fence porphyrins, 4,0-meso-tetrakis(2-hexanamidophenyl)porphyrin, tetraaryl substituted porphyrins, (5,10,15,20-tetrakis[4-(1-octyloxy)phenyl)]prophinato(copper-II), tetraphenyl porphyrins, tetrakis-(4-(hexadecyloxy)phenyl)porphyrin, tris(4-hexadecycloxy)-phenyl)(4-methylpyridinium)porphyrin tosylate, meso-diphenylbis(N-methyl-4-pyridyl)-porphyrin, tetraphenylporphine, and tetra(p-N-methylpryidyl)porphine. Illustrative types of cyanine dyes that can form J-aggregates include, but are not limited to, (5,6-dichloro-2-[3-[5,6-dichloro-1-ethyl-3-(3-sulfopropyl)-2(3H)-benzimidazolidene]-1-propenyl]-1-ethyl-3-(3-sulfopropyl), quino-2-monomethine, psuedoisocyanine, 1,1′-diethyl-4,4′-cyanine and 1,1′-diethyl-2,2′-cyanine. Illustrative types of imides that may be used as J-aggregates include, but are not limited to, perylene bisimides, naphthalenemonoimide, terrylene, perylene monoimide, and other rylenes. Other materials that may be used as J-aggregates include, but are not limited to polymethines, squarains, squaric acids, rotaxanes, xanthenes, and stilbenes. Additional chromophore assemblies and other chromophores are described in the commonly owned provisional application incorporated herein by reference.

In other examples, the devices and methods described herein may also include an anti-Stokes material. Illustrative anti-Stokes materials include, but are not limited to, the anti-Stokes material is selected from the group consisting of lanthanide complexes, thulium doped silicate glasses, europium complexes, terbium complexes, samarium complexes, dysprosium complexes, inorganic rare earth ions, inorganic rare earth crystals, bulk phosphor material, europium-activated yttriumoxysulphide, rare earth oxide nanocrystals, fluorides containing europium, chlorides containing europium, lanthanide phosphors, inorganic crystal lattice with trivalent rare earth dopants, yttriumoxysulphide activated with erbium and ytterbium, upconverting phosphor nanopowders, anti-Stokes phosphors FCD-546-1, FCD-546-2, FCD-546-3, FCD-660-2, FCD-660-3 and FCD-660-4, anti-Stokes phosphor LPG-IR-3, and laser detection anti-Stokes” phosphors PTIR545/UF, PTIR550/F and PTIR660/F.

In certain embodiments, assuming a point dipole radiation pattern where maximum emission occurs perpendicular to the dipole axis (as shown in FIG. 1B), the dependence of confinement efficiency on dipole axis is shown in FIG. 1C. The dipole axis angle is defined in FIG. 1D. Alignment of light emitters is strongly correlated to confinement efficiency, resulting in about a 20% or more gain in efficiency when compared to isotropic emission (where the refractive indices of the media are η_{core}=1.5 and η_{cladding}=1). Confinement efficiency has a strong effect on overall power conversion efficiency. Non-unity confinement can decrease light collection by direction reduction of photon quanta. For example, through the process of self absorption (or reabsorption) photons can be absorbed and emitted again. With each re-emission cycle, non-unity confinement further decreases photon quanta in the concentrator. Confinement losses can build up substantially lowering edge collection efficiency and overall power conversion efficiency. The magnitude of this effect is shown in FIG. 1E. In the graph of FIG. 1E, an η_{core}=1.8 and η_{cladding}=1 is assumed. By controlling the direction of emission, a 30% or more increase in conversion efficiency may be achieved. The top, dashed lines in FIG. 1E represent optimally aligned emitters for maximal confinement (e.g., greater than 90%). Certain embodiments described herein advantageously increase the efficiency of solar concentrators by selecting or tuning the emission direction and/or by aligning chromophores at a selected angle or in a selected direction.

In certain examples, chromophore emission may be controlled through physical alignment of light emitting species to reduce confinement losses in the energy transduction cycle of LSCs. For example, each emission species has a radiation pattern dependent on the spatial structure of its electronic energy levels. The physical orientation of the emitter is linked to its radiation pattern. By controlling physical orientations, direct control of confinement efficiency can be achieved.

In one embodiment, physical orientation may be controlled by trapping the chromophore in a matrix such that free rotation is limited and the chromophore molecules are oriented in a selected plane or direction. For example, where the chromophores used have a charge or a dipole moment, an electric field may be used to align the chromophores and keep the chromophores oriented in a certain direction. The electric field may be maintained during operation or, as discussed below, may be removed subsequent to one or more processing steps.

In certain examples, after alignment of the chromophores with the electric field, the matrix surrounding the chromophores may be polymerized or cross-linked to trap the chromophores in the oriented direction. If the overall size of the chromophores are about the same size or slightly smaller, e.g., 5-10% smaller, than the overall size of the void space where the chromophore resides, then free rotation may be limited and the general direction of the chromophore can be retained even after the electric field is removed.

In some examples, the chromophore may be added to a pre-polymerized matrix in a desired amount. In certain examples, it is desirable that the matrix be saturated with the chromophore such that the overall absorption and/or emission efficiency of the LSC can be increased. In certain examples, after polymerization of the matrix, a terminal chromophore can be coated onto the matrix such that light energy absorbed by the tuned chromophore molecules of the matrix can be transferred to the terminal chromophore. In other examples, the pre-polymerized matrix/chromophore mixture may be coated onto a substrate that includes an absorbing chromophore. Subsequent to coating, the mixture can be polymerized to provide a tuned terminal chromophore which can function to receive energy from the absorbing chromophore. To increase the overall efficiency of the LSC, it may be particularly desirable to use two or more different chromophores to separate the absorption and emission functions of the LSC.

In some examples, two or more chromophores may be added to the pre-polymerized matrix. For example, one of the chromophores may function to absorb light energy and the other may function to emit light energy. In certain embodiments, as discussed below, it may be desirable to orient the absorbing chromophore perpendicular to the incident light rays and/or parallel to the guiding direction. The absorbing chromophore can transfer energy to the emitting chromophore which can emit light in a selected direction. As discussed further below, the LSC can be oriented at a selected angle with respect to a PV cell to provide light to the PV cell.

In some examples, a first chromophore may be deposited in a first layer and oriented in a first direction. Crosslinking or curing of the layer can trap the chromophores in a certain direction. A second layer including the same or a different chromophore can then be deposited on the first layer. The orientation of the chromophore in the second layer may be the same as the orientation of the chromophores in the first layer or may be different across the whole range of possible orientations. Where two or more chromophores are used, each may be deposited, for example, in a thin film such as those thin films described herein and may be deposited in separate films or co-deposited in a single film.

In some examples, the polymer matrix may be a single type of material or may be a mixture of two or more materials. Where a single monomer is present in the polymer, e.g., a homopolymer, the monomer may be styrene, butadiene, ethylene, propylene, glucose or other suitable monomers. Illustrative homopolymers include polystyrene, polybutadiene, polyethylene, cellulose, polyarylenes, polyacrylates polymethacrylates and the like. In examples where a copolymer is present, the copolymer may be, for example, an AB diblock, an ABA triblock, an ABC triblock, or a starblock copolymer. Specific types of copolymers include, but are not limited to, styrene-butadiene-styrene (SBS), styrene-ethylene-butylene (SEBS), styrene-ethylene-propylene (SEPS) and other block copolymers including two or more different monomers.

In certain embodiments, the polymer may be polymerized by exposing it to increased temperature, ultraviolet light, one or more initiators or other conditions or materials that can cross-link or polymerize the monomers of the polymer. For example, a chromophore may be mixed with liquid polymer, an electric field may be applied, and then heat may be applied to cross-link the polymer and trap the chromophore in a certain orientation. In other examples, a chromophore may be mixed with liquid polymer, an electric field may be applied, and then the mixture may be exposed to ultraviolet light to cross-link the polymer and trap the chromophore in a certain orientation.

While alignment is described above using an electric field, other stimulus and perturbations may be used to orient the chromophores. For example, a magnetic field, charged species in the matrix, matrix ligands, etc. may be used to force the chromophore to align in a certain direction in the matrix. Such alignment may occur, for example, as the chromophore interacts through chemical and/or physical interactions with the matrix. In some examples, one or more charged groups of the matrix may chemically bond to the chromophore to constrain free rotation of the chromophore and orient the chromophore within the matrix. For example, the matrix may include internal ligands that comprise one or more functional groups capable of reacting with the chromophore. Illustrative functional groups include, but are not limited to, a siloxane, an amine, a phosphine, a phosphine oxide, a phosphonate, a phosphonite, a phosphonic acid, a phosphinic acid, a thiol, an alcohol, a hydroxyl group, a phenylhydroxy group and the like. In other examples, the matrix may include aromatic or heteroaromatic structures such that interaction of the pi system of a chromophore with the pi system of the aromatic can orient the chromophore. For example, stacking of aromatic structures, through pi-pi interactions, may occur within the matrix to align the chromophore molecules in a certain direction.

In certain embodiments, the emitting chromophore can be placed or added to a local environment to constrain its physical orientation. The local environment, or matrix, can be patterned or stretched to achieve anisotropy in its physical properties. In addition, the molecular structure of the matrix can be directly designed to favor a physical anisotropy as with block copolymers. The emitters can reside in this matrix and be sterically hindered to adopt a specific conformation to reduce its energetic interaction with the matrix.

As discussed above, some emitters possess a strong electronic dipole which can interact with local electronic fields. If the dipoles exist within a liquid or viscous medium, they can rotate or align to the electric field, lowering their free energy. This is the physical mechanism affecting operation of liquid crystal displays (LCDs). For both LCD's and LSC's, the optical transmission properties of the aligned dipoles can be controlled. Dipole alignment to an electric field can be utilized during the manufacturing process of LSC's, after which the position can be frozen through various methods, including light or heat induced polymerization of the matrix material. In some examples, liquid crystals may be doped into the matrix such that alignment of the liquid crystal in the electric field also results in alignment of the chromophore within the electric field. Where the chromophore molecule is anisotropic, different optical properties may be provided versus the use of an isotropic chromophore. The tuned chromophores described herein may be isotropic, anisotropic or include a mixture of isotropic and anisotropic species to provide desired optical properties. Similarly, isotropic and anisotropic liquid crystals may be used to alter the optical properties of the LSC as desired.

In certain embodiments, for LSC's that are formed of an emissive material on a waveguide substrate, the emitters can be aligned to the interface between the coating and substrate through direct self assembly. For instance, the emitters can covalently bind to the substrate and pack densely to maximize interface linkage. Depending on emitter physical structure, dense packing can result in physical alignment. For instance, the linear physical structure of alkanethiols and octedecyltrichlorosilanes result in self assembly of monolayers on metallic and oxide substrate, respectively. These layers can be deposited sequentially, retaining alignment throughout. The overall distribution of the self-assemblies can vary, and in certain examples, there may be a substantially uniform distribution of species along the surface of the device. In other examples, the substrate can be masked prior to addition of the chromophores such that only certain regions of domains include the self-assembled chromophores. In some examples, regions may be etched away to remove self-assembled chromophores in certain areas.

In certain embodiments, the terminal chromophore can be oriented within a supramolecular aggregate where only a portion of the aggregate emits light and the rest of the aggregate functions as an antenna to funnel absorbed light to the emitter. These aggregates can be linked by chemical bonds, constraining the orientation of emitters relative to the rest of the aggregate. Alternatively, these aggregates can be linked by physical interactions with each other to form a complex or assembly of components that have different functions in the overall assembly. For example, one component of the complex may function to absorb incident light and another component of the complex may function to emit the light, e.g., function as a terminal chromophore. Illustrative aggregates and complexes are described, for example, in commonly owned U.S. Provisional Application No. 61/146,550 incorporated herein by reference, the entire disclosure of which is hereby incorporated herein by reference for all purposes.

In certain examples, the physical alignment emitters in an operational LSC can fall within a restricted angular range if, during fabrication, a subset of emitters can be deactivated. For instance, if a fabrication method is used that results in an isotropic emitter pattern, a subset can be turned off, resulting in narrower angular range of emitters. This deactivation can be controlled if the emitters exhibit an anisotropic interaction with some deactivating force. For instance, this could be absorption and oxidation followed by absorption of high energy electromagnetic radiation or a particle stream. The anisotropic interaction could be due to polarization or directionality of incoming radiation. The interaction may be due to the presence of an additive in the device that results in deactivation of certain chromophore molecules. For example, a quencher can be added to certain areas of the LSC such that chromophores near the quencher do not substantially emit light. In some examples, the deactivator or deactivating force may be constructed and arranged to provide a desired emission pattern. For example, the device may be constructed such that only a small slit or linear portion of the device emits light whereas other portions are designed to absorb incident light but do not substantially emit. Such configuration permits coupling of a PV cell to the LSC at a specific region to provide emitted light at a specific angle.

In certain embodiments, for LSCs that are formed of a coating of an emissive material on a waveguide substrate, the physical orientation can be controlled if the emitter resides in a viscous medium that is extruded through a small opening. For instance, die heads in roll coaters can include very small fluid output slits. During fluid travel through these slits, materials (both emitters and the matrix) can align to the travel direction and be coated in an anisotropic manner. After coating solidification, the anisotropy can be retained, triggered by thermal or photo treatments.

In other examples, the chromophore may be placed in a material that can undergo a transition with temperature. For example, at high temperatures the material may undergo a transition to become more viscous or less viscous. Similarly, materials may be selected that become more or less viscous as temperature is decreased. Illustrative materials include, but are not limited to, sols, gels, hydrogels and the like. Where such materials are present, the LSC may include a layer of the material encapsulated by two or more surfaces to prevent loss of the material. For example, a small amount of the material may be inserted between glass plates, e.g., high refractive index glass plates, and the glass plates can be sealed to prevent loss of the material. The temperature may be controlled through the use of active heating or cooling elements or the material may be selected based on the intended use temperature to provide a desired viscosity at the use temperature. Illustrative viscosities that may be present include, but are not limited to, about 1 cPs to about 5000 cPs, more particularly about 10 cPs to about 500 cPs, for example, about 75 cPs. In addition, where the viscosity is too low or too high, one or more thixotropic agents may be added to alter the viscosity to a desired value or range.

In some examples, the viscous medium may be used to hold or retain the orientation of the chromophores for such a time until the chromophore can be fixed by other means, e.g., cross-linking of the matrix. In such embodiments, the viscous medium may subsequently be removed to avoid any unnecessary optical effects that may be produced from the presence of the viscous medium. Such removal may be accomplished by washing, evaporation or other suitable processes. In certain examples, the viscous medium can participate in cross-linking of the matrix such that the resulting polymer is a combination of monomer matrix species and the components of the viscous medium. Other uses of a viscous medium to align the chromophores will be selected by the person of ordinary skill in the art, given the benefit of this disclosure.

Additional methods may be employed to increase the product of absorption and confinement efficiency involves the use of an optical element situated between the coated substrate and the illumination source and separated by a physical gap. The optical element functions or is operative to redirect the angle of incidence of the incoming light from the sun. An example of an optical element is a light diffusing plate. By using a diffusing plate, light which is principally incident near normal to the solar concentrator can be distributed to a wider range of angles. When an optical element is used, direct light can be transformed into diffuse light. In this configuration, light may be absorbed with high efficiency by chromophores oriented to increase confinement efficiency. Diffusing plates and other optical elements to redirect light can be used independently or in addition to energy transfer.

Referring to FIG. 1F, another example of a solar concentrator system is shown. In the illustrated example, the system 1100 comprises a diffusing plate 1110 disposed above an LSC 1120 coupled to a PV cell 1130. As discussed above, the LSC 1120 includes a substrate 1140 having a chromophore 1150 disposed therein to absorb and redirect light 120 to the PV cell 1130 coupled to an edge of the substrate 1140. The diffusing plate 1110 is operative to change the direction of the optical radiation 110 before it is incident on the substrate 1140. In one example, the diffusing plate 1110 is configured for Lambertian scattering of the optical radiation 120. In certain examples, numerous different types of light diffusers may be used with an LSC, and the exact type and nature of the diffuser is not critical. Illustrative light diffusers for use with a LSC include, but are not limited to, opalescent glass, frosted glass, mechanically roughened plastics and glasses, chemically roughened plastics and glasses, surface-pattered plastics, and holographically patterned plastics. In one example, anti-reflection coatings (not shown) may be provided on the upper surfaces of either (or both) of the diffusing plate 1110 and/or the substrate 1140 to reduce or prevent reflection of the optical radiation 120 away from the solar concentrator.

A Monte Carlo simulation was performed for a solar concentrator such as that illustrated in FIG. 1F to illustrate the optical quantum efficiency of such a system for various orientations of the chromophore 1150. For this simulation, it was assumed that one chromophore 1150 absorbs and emits. The chromophore loading of the substrate 1140 is such to yield 95% absorption for light incident at 30 degrees in a single pass of light having a wavelength of 600 nm. A cosine-squared emission pattern was assumed, which results in highest confinement efficiency for emitters oriented at 90 degrees. Orientation of the chromophores (emitters) was specified relative to the front face of the LSC 1120. A diffusing plate 1110 with Lambertian scattering is placed above the LSC 1120. The LSC 1120 has dimensions corresponding to a geometric gain, G, of 250. The results of this simulation are illustrated in FIGS. 1G, 1H and 1J.

FIG. 1G illustrates optical quantum efficiency as a function of the angle of incidence of the optical radiation (vertical axis) and the orientation of the chromophore (horizontal axis), for the above simulation. The optical quantum efficiency is nearly constant and highest for a chromophore orientation of between about 70 degrees and 90 degrees.

Referring to FIG. 1H, a plot of the optical quantum efficiency (vertical axis) as a function of the orientation of the chromophore (referred to as molecular orientation) is shown. The light is perpendicularly incident (i.e., at 90 degrees relative to the plane of the diffusing plate) on the diffusion plate with Lambertian scattering. As can be seen from FIG. 1H, the optical quantum efficiency increases with an increasing degree of molecular orientation, and is relatively constant and highest for about 70 degrees to 90 degrees.

FIG. 1J is a plot of the optical quantum efficiency (vertical axis) as a function of the angle of incidence of the light (horizontal axis) relative to the plane of the diffusing plate 1110 for several orientations of the chromophore. Line 1180 represents a molecular orientation of 90 degrees, line 1170 represents a molecular orientation of 80 degrees, and line 1160 represents a molecular orientation of 70 degrees. As can be seen from FIG. 1J, the optical quantum efficiency is similar among the various molecular orientations and approximately constant for light incident at an angle above about 30 degrees. This result demonstrates that the power output of the solar concentrator will remain substantially constant with varying angles of incidence of the optical radiation 120 on the diffusing plate 1110. For example, as the sun moves across the sky during the day and the angle of incidence of the solar radiation therefore changes, the power output of the solar concentrator may remain substantially constant as solar radiation is incident at less than 30 degrees only very early and late in the day. Thus, by using the diffusing plate 1110 coupled to an LSC 1120, the power output of the solar concentrator may be maintained at a substantially constant level even when changing light conditions are present. Furthermore, as discussed above, the use of the LSC may increase the power output of the PV cell(s) associated with the concentrator system relative to PV cells that receive non-concentrated light, thereby extending the usefulness of PV systems.

In producing an LSC whose light emission properties are controlled, the device may be evaluated to measure the intensity of light emission as a function of emission angle. For example, the light emission at various angles may be measured and the LSC can be oriented with respect to a PV cell to provide maximum light emission to the PV cell. To orient the PV cell, a wedge coating or other suitable material may be disposed on the PV cell to provide a desired angle between the LSC and the PV cell. It is desirable that the wedge coating include substantially optically transparent materials such that light emission from the LSC is not absorbed by the wedge coating.

In certain embodiments, the chromophores used herein may be non-semiconducting materials. That is, the chromophores used in the LSCs described herein may be dye molecules, chromophore complexes, chromophore assemblies, etc. which do not function as a semiconductor or have semi-conducting properties.

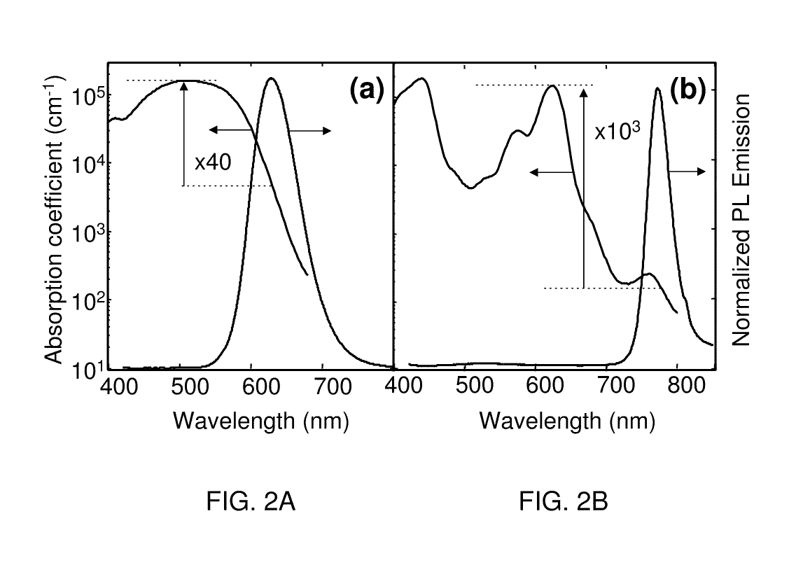

The LSC's described herein may include one, two or multiple chromophores any of which may be tuned as described herein. For a typical chromophore, the ratio of self absorption to the chromophore's peak absorption is desirably on the order of the concentration factor G. For example, for a 2 mm thick waveguide that is 1 meter wide, the concentration factor G is 500. The self-absorption is desirably less than 1/5000th of the peak absorption of the chromophore to have significant radiation reaching the edge. For example, the classic laser dye DCM (4-dicyanomethylene-2-methyl-6-(p-(dimethylamino)styryl)-4H-pyran), which was preferred by Batchelder et al. (Batchelder et al., Applied Optics, 18(18), 3090 (1979) has a normalized self absorption of approximately 5%, which limits the concentration factor to G of about 2. In contrast, certain chromophores used herein provide significant advantages when used in LSC's. Two examples of such chromophores are shown in FIGS. 2A and 2B. Referring to FIG. 2A, absorption and emission spectra from DCTJB (4-(dicyanomethylene-2-t-butyl-6(1,1,7,7-tetramethyljulolidyl-9-enyl)-4H-pyran) are shown. The absorption ratio between absorption peak and emission peak for DCTJB is about 50. Referring to FIG. 2B, absorption and emission spectra for Pt[tptb] (platinum tetraphenyltetrabenzoporphyrin) are shown. The ratio of the absorption coefficient peak at the peak absorption wavelength to the absorption coefficient at the peak emission wavelength for Pt[tptb] is several hundred or more. In some examples, materials that provide a ratio of the absorption coefficient peak at the peak absorption wavelength to the absorption coefficient at the peak emission wavelength of 40 or more may be used in the solar concentrators disclosed herein. One or more of the DCTJB and Pt[tptb] species may be aligned in the device to provide a tuned chromophore.

In certain examples, first and second chromophores may be disposed on or in a substrate and may be selected to exploit Förster near field energy transfer. Förster near field energy transfer couples the transition dipoles of neighboring molecules and may be exploited to couple one chromophore with a short wavelength absorption to a second chromophore with a longer wavelength absorption. For example, the concentrator may be configured with closely spaced chromophores. As used herein, the term “closely-spaced” refers to positioning or arranging the chromophores adjacent to or sufficiently close to each other such that Förster near field energy transfer may occur from one of the chromophores to the other chromophore. Such transfer of energy generally occurs without emission of a photon and results in an energy shift between absorption and emission. It is desirable that at least one of the chromophores be a tuned chromophore such that the optical properties may be controlled. In particular, it is desirable that the terminal chromophore be a tuned chromophore such that the emission direction may be controlled.

In certain examples, at least first and second closely spaced chromophores may be disposed on or in the substrate in a manner to receive optical radiation. The first chromophore may be effective to absorb at least one wavelength of the optical radiation and may be arranged to transfer energy by Förster energy transfer to the second chromophore. The second chromophore may be effective to emit the transferred energy at a wavelength that is red-shifted from the wavelength absorbed by the first chromophore. The second chromophore is typically a tuned chromophore such that the emission direction may be controlled. For example, the second chromophore may be susceptible to alignment in an electric field. The use of two chromophores as described above may improve the overall efficiency of the solar concentrator by reducing self-absorptions. In one illustration, the first chromophore may be tris-(8-hydroxylquinoline) aluminum (AlQ3) or rubrene, or both, and the second chromophore, which emits light, may be DCM or a tunable derivative thereof. Both of tris-(8-hydroxylquinoline) aluminum or rubrene are fluorescent at high concentrations and have suitable electronic properties that permit energy transfer to DCM. In some examples, the chromophore may be a perylene or terrylene diimide molecule or a molecule having at least one perylene or terrylene diimide unit in it, e.g., a derivatized perylene or terrylene diimide chromophore. The second chromophore may include accessory ligands or substituents that alter the electronic properties and render the chromophore susceptible to orientation in an electric field. Alternatively, the second chromophore may be tuned using the other devices and methods described herein, e.g., viscous media, matrix trapping, liquid crystals, etc.

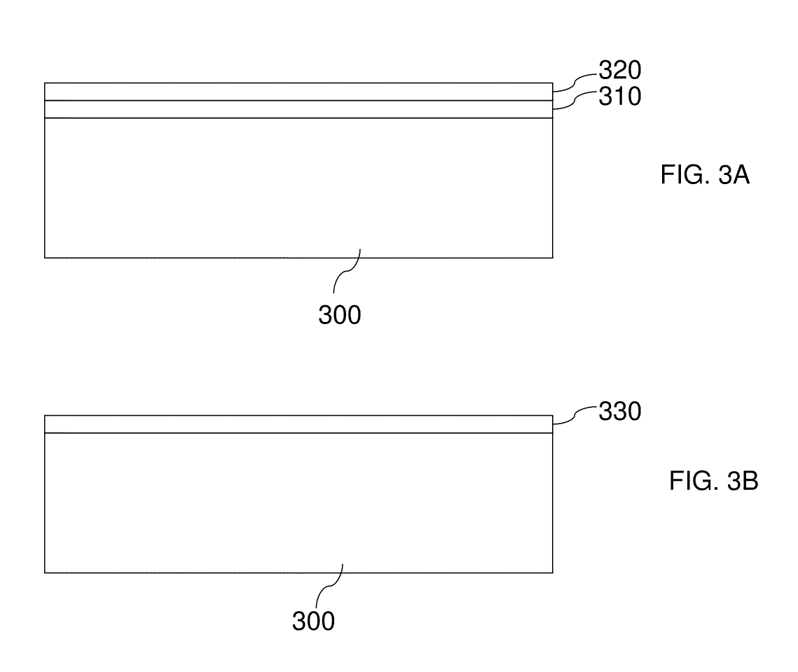

In certain examples, to take advantage of the Förster energy transfer, which is typically a short range interaction occurring over 3-4 nm, the chromophores may be disposed in one or more thin films on a substrate. For example and referring to FIG. 3A, a thin film of a first chromophore 310 may be disposed on a substrate 300. A thin film of a second chromophore 320 may be disposed on the first chromophore 310. The second chromophore may be disposed with a viscous medium or may reside in a cross-linkable material such that the orientation of the second chromophore can be controlled.

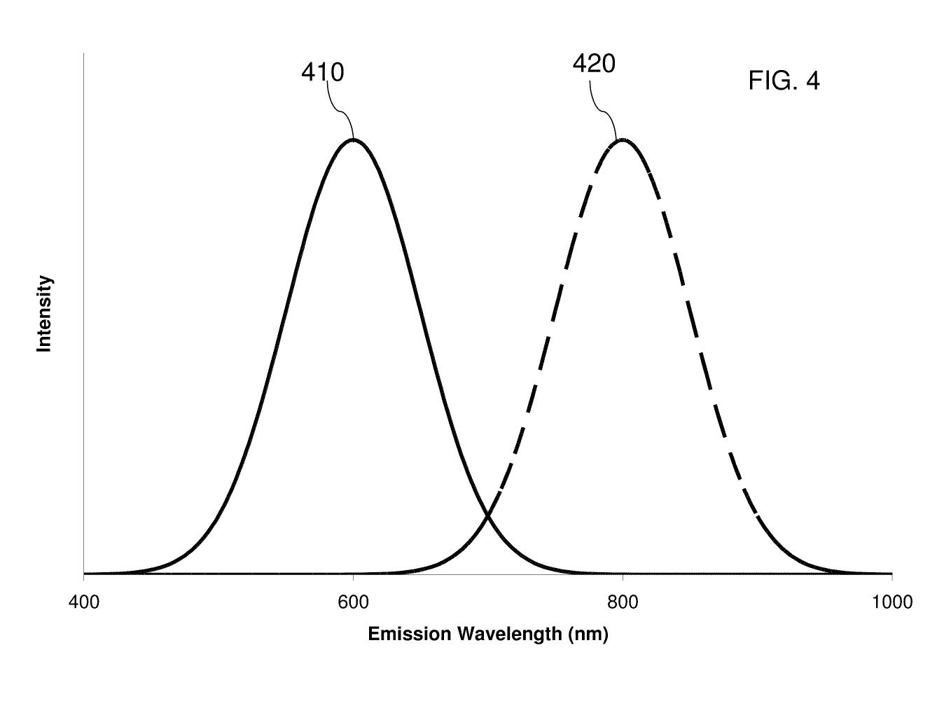

In an alternative configuration as shown in FIG. 3B, the chromophores may be mixed together and disposed simultaneously on the substrate 300 to provide a thin film 330 or may be co-evaporated on the substrate 300 to provide a thin film 330. In certain instances, where orientation of the second chromophore is desired, both chromophores can be subjected to the same stimulus, e.g., electric field, magnetic field, matrix trapping, viscous medium, etc. without adverse effects on the first chromophore. The exact thickness of the thin film may vary, and in certain examples, the film is about 0.5 microns to about 20 microns, more particularly about 1 micron to about 10 microns. In some examples, the Förster energy transfer ensures red-shifting of the emission. Such red-shifting provides the advantage of reducing the emission spectrum overlap with the absorption spectrum, which could decrease the overall efficiency of the solar concentrator. For example and referring to FIG. 4, the Förster energy transfer can result in shifting of the light emission to a higher wavelength 420 as compared to the wavelength emission 410 in the absence of Förster energy transfer. Such shifting reduces the overlap between the absorption and emission spectra thus reducing the likelihood of reabsorption.

In accordance with certain examples, to favor Förster energy transfer, it may be desirable to incorporate different amounts of the various chromophores into the solar concentrators. For example, it may be desirable to use substantially lower amounts of the chromophore that emits the light and higher amounts of the chromophore that transfers the energy by Förster energy transfer. In some examples, at least five times more of the chromophore absorbing the optical radiation, e.g., the solar radiation, is present as compared to the amount of light emitting chromophore that is present. In other examples, at least ten times more of the chromophore absorbing the optical radiation is present as compared to the amount of light emitting chromophore that is present. Suitable ratios of light absorbing chromophores to light emitting chromophores will be readily selected by the person of ordinary skill in the art, given the benefit of this disclosure.

In accordance with certain examples, it may be desirable to use multiple different chromophores to absorb the optical radiation and a single terminal chromophore to emit light to the PV cell. The terminal chromophore may be disposed adjacent to or near the PV cell such that light emission occurs in proximity to the PV cell. In addition, the terminal chromophore may be tuned such that light emission occurs substantially in a single direction. For example, two or more chromophores that absorb light at different wavelengths may be disposed on or in the substrate. Each of the chromophores may be configured such that they transfer energy to one or more terminal chromophores that emit light, e.g., the chromophores that absorb light do not substantially emit light by fluorescence or other radiative transition pathways. The terminal chromophore may emit light in a substantially single direction or at a substantially narrow angle to a PV cell optically coupled to the solar concentrator. In some examples, the terminal chromophore may be selected such that its light emission is red-shifted from the absorption spectrum of the other chromophores to reduce the likelihood of re-absorption events that may lower the efficiency of the device.

In certain examples, the chromophores may be disposed on the substrate as shown in FIGS. 3A and 3B, whereas in other examples, the chromophores may be in the substrate itself, e.g., embedded, impregnated, injected into, co-fabricated with or the like. For example, the chromophores may be dispersed within the substrate body or the substrate itself may be produced by disposing various thin films onto each other with the chromophores disposed in a thin film between two or more layers of the thin film substrate. The overall thin film stack may make up the entire solar concentrator device. In some examples, the terminal chromophore may be disposed in a manner to permit orientation or alignment in a selected plane. For example, during production, the thin film may include matrix components that can be cross-linked to trap the terminal chromophore and orient the terminal chromophore in a selected orientation.

In certain embodiments, the solar concentrators disclosed herein may be configured such that light emission to the PV cell occurs by phosphorescence. As a chromophore absorbs optical radiation, an electron is promoted from the highest occupied molecular orbital (HOMO) to the lowest unoccupied molecular orbital (LUMO). The excited state may take several forms or spin states including singlet states and triplet states. For molecules with strong fluorescence, the singlet state has a strongly allowed radiative transition to the ground state. For molecules that emit light by phosphorescence, the radiative transition from triplet excited state to singlet ground state is spin forbidden and is also lower in energy than decay from a singlet state. Thus, the emission wavelength of phosphors is Stokes shifted (shifted to longer wavelengths) and also occurs for longer periods due to the spin forbidden nature of the transition. In addition, by aligning the terminal chromophore through trapping or other means, phosphorescence emission may be enhanced, which can increase the overall efficiency of the device.

In certain examples, the compound disposed on or in the waveguide may be an organometallic compound. In some examples, the organometallic compound may include a transition metal bonded, chelated or coordinated to one or more ligands. Such ligands may include groups having lone pair electrons that may be used to coordinate the metal center. The transition metal may be charged or uncharged and the overall complex may adopt many different geometries including, for example, linear, angular, trigonal planar, square planar, tetrahedral, octahedral, trigonal pyramidal, square pyramidyl, trigonal bipyramidal, rhombic and the like. Such organometallic compounds may be susceptible to alignment in an electric field due to charge separation resulting between the metal center and the accessory ligands. In the alternative, one or more unoccupied sites of the metal may form a complex with a ligand of a matrix to trap or hold the organometallic at a certain angle or orientation. For example, an organometallic compound having fewer ligands than desired may be added to a matrix, and the ligands of the matrix may covalently bond to the metal center to retain organometallic within the matrix. If desired, the matrix can be cross-linked to further constrain movement or rotation of the organometallic compound within the matrix.

In certain examples, the compound disposed on or in the substrate may be a porphyrin compound. In some examples, the porphyrin compound has a general formula as shown in formula (I) below.

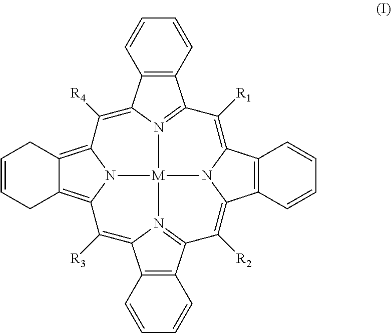

In some examples, each of R₁, R₂, R₃ and R₄ of formula (I) may independently be selected from a saturated or unsaturated hydrocarbon (e.g., a linear, branched or cyclic, substituted or unsubstituted hydrocarbon) having between one and ten carbon atoms, more particular having between one and six carbon atoms, e.g., between four and six carbon atoms. In certain examples, each of R₁, R₂, R₃ and R₄ may independently be selected from one or more of alkyl, alkenyl, alkynyl, aryl, aralkyl, naphthyl and other substituted or substituted hydrocarbons having one to ten carbon atoms. In some examples, at least one of R₁, R₂, R₃ and R₄ may include at least one non-carbon atom, e.g., may include at least one oxygen atom, one sulfur atom, one nitrogen atom or a halogen atom. In some examples at least one of R₁, R₂, R₃ and R₄ may be a heterocyclic group. In one embodiment, each of R₁, R₂, R₃ and R₄ is a substituted or unsubstituted aryl group. In some examples, each of R₁, R₂, R₃ and R₄ is benzyl (C₆H₅) as shown below in formula (II).

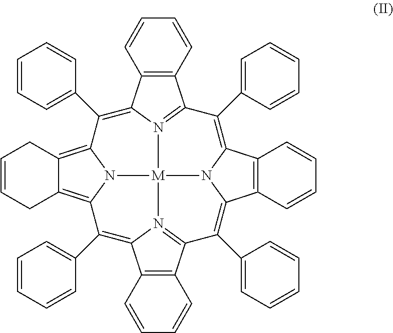

In formulas I and II, M may be any metal. In some examples, M may be a transition metal such that spin-orbital coupling is promoted to favor phosphorescence emission over fluorescence emission. In some examples, M may be a “heavy atom” having a atomic weight of at least about 100, more particularly at least about 190, e.g., an atomic weight of 200 or greater. In certain embodiments, M may be iridium, platinum, palladium, osmium, rhenium, hafnium, thorium, ruthenium and metals having similar electronic properties. Additional metals and groups for use in porphyrin compounds for use in a solar concentrator will be readily selected by the person of ordinary skill in the art, given the benefit of this disclosure.

In some examples, the aryl ligands of the porphyrin compounds may include substituents that are charged or that can interact with, or react with, a matrix to orient the porphyrin compounds in the matrix. For examples, the aryl substituents may include para-substituents such as, for example, amino groups, hydroxyl groups, sulfonyl groups, phoshpo groups and the like, that can react with one or more groups of the matrix to anchor and/or orient the porphryin in the matrix. As discussed herein, to further anchor or retain the orientation of the porphyrin, the matrix may be subsequently cross-linked.

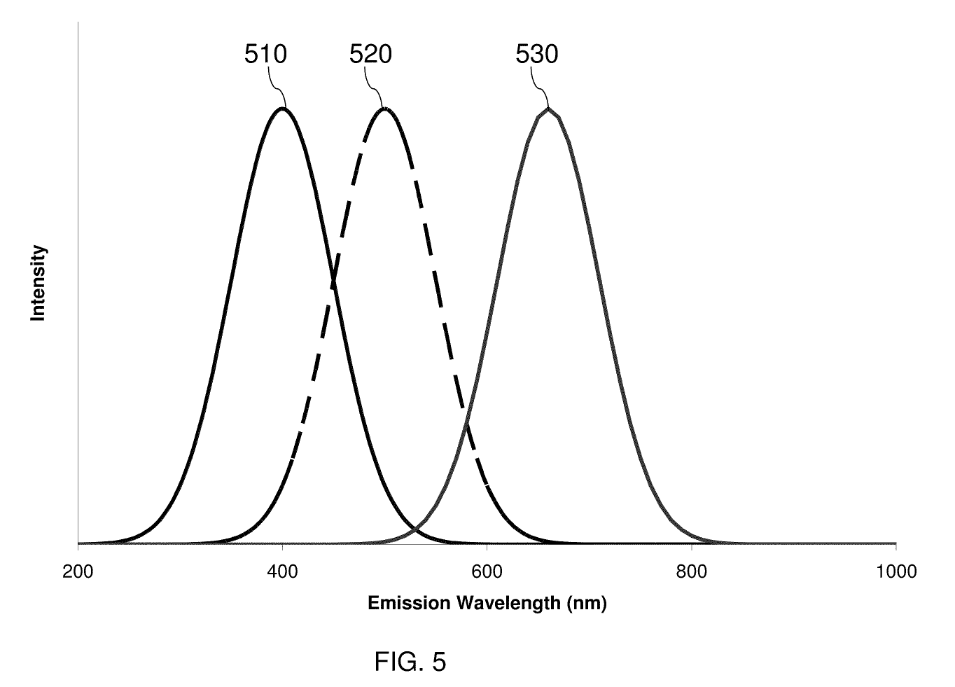

In accordance with certain examples, a composition comprising a material effective to absorb optical radiation within a first wavelength range and to emit the absorbed optical radiation by phosphorescence within a second wavelength range that is red-shifted from the first wavelength range is provided. In certain examples, the first and second wavelength ranges do not substantially overlap in wavelength. As used herein, “do not substantially overlap” refers to overlap by less than about 50 nm, more particularly less than about 20 nm, e.g., less than about 15 nm. By selecting a composition that has reduced or substantially no overlap between the absorption wavelength spectrum and the emission wavelength spectrum, the overall efficiency of the LSC may be increased by, for example, reducing re-absorption. Selection and design of phosphors can result in shifting of the emission wavelength to higher wavelengths and thus reduce or eliminate spectral overlap. An example of this feature is shown in FIG. 5. The absorption wavelength spectrum 510 is shown as being blue-shifted (anti-Stokes shift) from the phosphorescence emission wavelength spectrum 530. In contrast, there may be substantial overlap between the absorption wavelength spectrum and the fluorescence wavelength spectrum 520. By selecting suitable compositions that decay primarily by phosphorescence emission, the spectral overlap between the absorption and light emission may be substantially reduced or eliminated. In addition to the above, the emission direction of the material may be controlled by aligning or orienting the material. The combination of reduced re-absorption with directed emission provides substantial advantages not achieved with existing LSCs.

In accordance with certain examples, the compositions for use in the LSC's disclosed herein may include one or more agents designed to red-shift the emission. Such red-shifting agents may be integral to the composition or may be added or doped into the composition in an effective amount to shift the light emission to longer wavelengths. Such red-shifting agents include, but are not limited to, heavy metals, chelators, compositions having one or more conjugated ring systems, matrix materials to trap the chromophore in and the like. In some examples, one or more steric groups may be added to limit or slow movement of the chromophore or to interact with, or affect, the pi-orbital systems of the chromophore. In some examples, the red-shifting agent and the emitting chromophore may both be susceptible to alignment or orientation, whereas in other examples, the emitting chromophore may be oriented or aligned but the red-shifting agent does not substantially align or orient in any preferred direction or orientation.

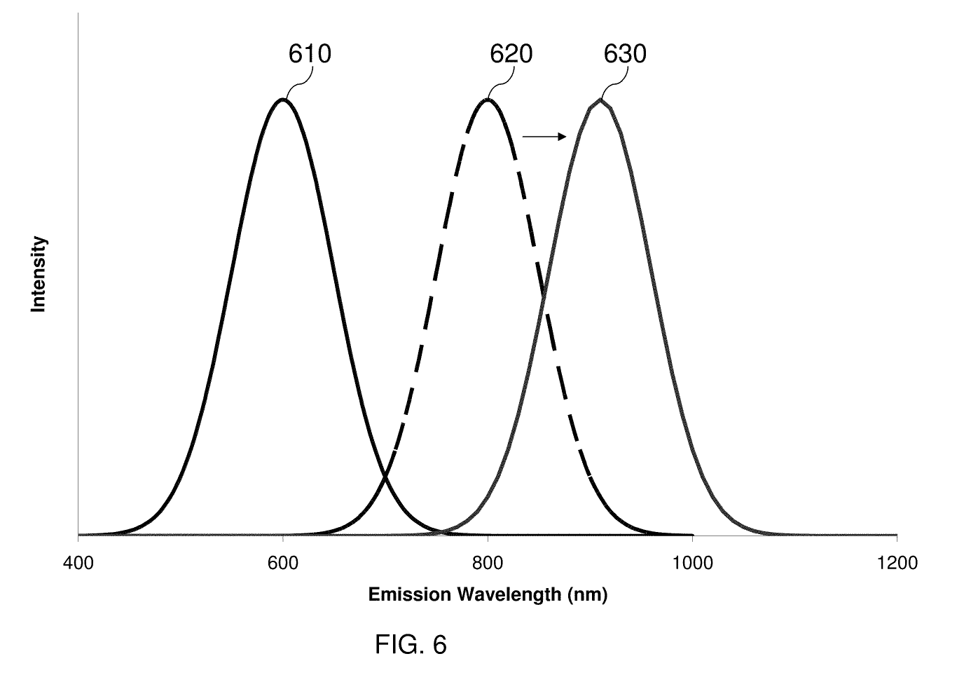

In accordance with certain examples, the solar concentrator may include a porphyrin compound and a red-shifting agent. In some examples, the red-shifting agent may be effective to shift the wavelength of the chromophore, e.g., a metalloporphyrin compound, to a longer emission wavelength than that observed in the absence of the red-shifting agent. An illustration of this red-shifting is shown in FIG. 6. A light absorption spectrum 610 is shown as being blue-shifted in comparison to a light emission spectrum 620. By doping the waveguide with a red-shifting agent, or including or otherwise depositing or co-depositing a red-shifting agent with the chromophore, the light emission spectrum may be red-shifted to a higher wavelength, as shown by light emission spectrum 630. As described herein, the porphyrin compound may be susceptible to orientation or may be anchored to a matrix to orient the porphyrin compound in a certain direction or orientation.

In certain embodiments, the solar concentrator may include one or more chromophore complexes or chromophore assemblies as described in the commonly assigned application incorporated herein by reference.

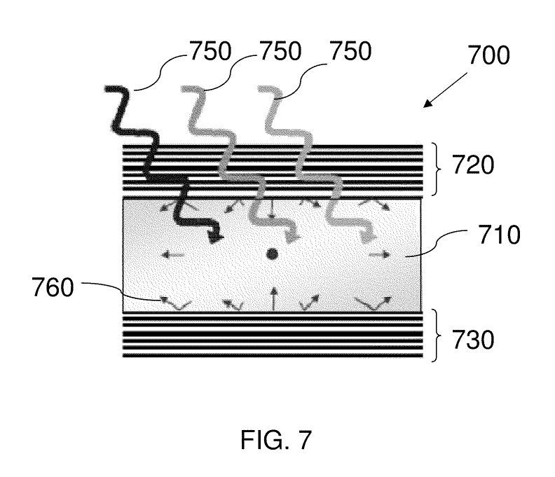

In certain examples, the devices disclosed herein may include one or more wavelength selective mirrors disposed thereon. In some examples, the wavelength selective mirrors may serve to increase the efficiency further by confining reflections within the substrate. For example, as solar radiation is incident on the solar concentrator some of the incident light may be reflected away from the substrate resulting in lower capturing of the light. By including at least one wavelength selective mirror on a surface of the solar concentrator, the light may be retained internally and provided to one or more PV cells coupled to the solar concentrator. An illustration of this configuration for a solar concentrator is shown in FIG. 7. The device 700 comprises a substrate 710 comprising one or more chromophores disposed on or in the substrate 710, as described herein. The device 710 also comprises a first reflective mirror 720 on a first surface and a second reflective mirror 730 on an opposite surface. The first selective mirror 720 may be configured such that light of certain wavelengths, shown as arrows 750, is permitted to be passed by the first selective mirror 720 into the substrate 710. The first selective mirror 720 may be designed such that reflected light, such as reflected light 760, is retained with the substrate, e.g., the reflected light is reflected back into the substrate by the first selective mirror 720. Similarly, the second selective mirror 730 may be designed such that it reflects incident light back into the substrate 710. The use of reflective mirrors permits trapping of the light within the substrate to increase the overall efficiency of the device 700. When reflective mirrors are used in combination with a tuned chromophore, the amount of light provided to a PV cell can be greatly increased.

In certain examples, the wavelength selective mirrors may comprise alternating thin films of, for example, one or more dielectric materials to provide a thin film stack than is operative as a wavelength selective mirror. In some examples, the thin films stacks are produced by disposing thin film layers having different dielectric constants on a substrate surface. The exact number of thin films in the thin film stack may vary depending, for example, on the materials used, the desired transmission and reflection wavelengths and the like. In some examples, the thin film stack may include from about 6 thin film layers to about 48 thin film layers, more particularly about 12 thin film layers to about 24 thin film layers, e.g., about 16 thin film layers to about 12 thin film layers. The exact materials used to produce the thin film layers may also vary depending on the desired number of thin films layers, the desired transmission and reflection wavelengths and the like. In some examples, a first thin film may be produced using, for example, a material such as polystyrene, cryolite and the like. A second thin film may be disposed on the first thin film using, for example, metals such as tellerium, zinc selenide and the like. In some examples, each of the thin films may have a thickness that varies from about 20 nanometers to about 100 nanometers, more particularly, about 30 nanometers to about 80 nanometers, e.g., about 50 nanometers. One advantage of using thin films is that mirrors comprised of thin films may permit retention of light at all angles of incidence and polarizations to further increase the light trapping efficiency of the solar concentrator. Solar concentrators having such thin film mirrors can receive more light thus increasing the efficiency of the solar cell device.

In accordance with certain embodiments, to further decrease re-absorption of the light, it may be desirable to alter the local environment of the chromophores using an additive. The local environment can affect the electronic properties of the chromophores such that chromophores having the same composition but in different local environments may have different optical properties, e.g., different emission wavelengths. In certain examples, the environment of the chromophore may be altered or tuned such that the ground state or neutral chromophore (not excited by light) behaves differently than the excited molecule. For example, the environment of the chromophore may include, or be doped with, another molecule that is charged or has a high degree of charge separation, e.g., a high dipole moment. As the excited state of many chromophores exhibits a large dipole moment, if the excited chromophore has spatial or rotational degrees of freedom, it can move or rotate to decrease the energy of the system which generally results in red-shifting of the emission wavelength. As discussed elsewhere herein, red-shifting of the emission spectrum can result in a decrease in the absorption and emission spectra, which decreases the likelihood of re-absorption and increases the overall efficiency of the solar concentrator. In some examples, an additive combined with a matrix or a stimulus to align the chromophore can provide for substantial control of the emission direction and/or properties of the chromophore.

In certain examples, the local environment of the chromophore may be altered by adding or doping a molecule into the substrate and/or co-depositing the molecule with the chromophore. Such doping or co-depositing can result in solid state solvation of the chromophore and alter the electronic properties of the excited state to alter the emission wavelength. In some examples, an effective amount of the dopant may be added to the molecule such that the emission wavelength is red-shifted by about 5 nm to about 50 nm, more particularly about 10 nm to about 40 nm, e.g., about 20 nm to about 30 nm. The exact nature of the composition used as a dopant may vary and, in particular, molecules having a dipole moment of at least 2 debyes, more particularly at least 3 debyes, e.g., about 5 debyes or more may be used. In some examples, the dopant may provide a polar matrix that alters the optical properties of the chromophore. In certain examples, as described herein, the polar matrix may covalently bond to the chromophore, whereas in other examples, the polar matrix may physically interact with, but not bind to, the chromophore.

In certain examples, the concentration of the dopant may be from about 0.5% to about 99%, more particular about 1% to about 90%, based on the weight of the host material. For example, if 10% by weight of dopant is used, then when the entire mass of the film is considered, 10% of its mass is from the dopant. The dopant may be any material, other than the emitting chromophore, that may alter the local environment of the emitting chromophore. For example, the host material itself may be considered a dopant if it alters the local environment of the emitting chromophore. In some examples, the dopant may be one or more materials including, but not limited to, tris(8-hydroxyquinoline), laser dyes such as, for example, 2-methyl-6-[2-(2,3,6,7-tetrahydro-1H,5H-benzo[i,j] quinolizin-9-yl)-ethenyl]-4H-pyran-4-ylidene] propane dinitrile (DCM2), camphoric anhydride, indandione-1,3 pyridinium betaine compounds, and azobenzene chromophores. Additional dopants and concentrations to alter the local environment of a chromophore will be readily selected by the person of ordinary skill in the art, given the benefit of this disclosure. It is particularly desirable to use a dopant in combination with one or more of the other materials or method described herein to align or orient a chromophore such that added control of chromophore emission is provided.

In some examples, the dopant itself may be present in an amount that permits transfer of energy, and optionally emission of light by the dopant, but not at so high a concentration or amount that substantial direct light absorption by the dopant itself occurs. For example, it may be desirable to select suitable concentrations of the materials such that light absorption by one of the species dominates. In some examples where a dopant is present, the dopant may be present at an amount such that direct light absorption by the dopant is 15% or less, e.g., 10% or less or 0-5%, of the total photons incident on the device. It will be within the ability of the person of ordinary skill in the art, given the benefit of this disclosure, to select suitable amounts of the materials in the LSC's disclosed herein such that one or more desired species preferentially absorbs light and one or more desired species preferentially emits light.

In accordance with certain examples, the efficiency of photon trapping by the solar concentrator may depend, at least in part, on the angle or orientation of the emitting chromophore. Chromophores oriented to absorb maximally may have a low trapping efficiency, whereas chromophores oriented to trap efficiently may absorb weakly. By controlling the orientation of the chromophores, both light trapping efficiency and light absorption may be increased. In particular, the orientation of the terminal chromophore, e.g., the light emitting chromophore may be selected such that light trapping efficiency is maximized. In embodiments where energy transfer is used to provide energy to the terminal chromophore, the weak light absorption by the terminal chromophore is not relevant. The absorbing chromophores may be either randomly oriented or oriented to jointly optimize light absorption and energy transfer efficiency to the terminal chromophore. It will be within the ability of the person of ordinary skill in the art to design solar concentrators that include selectively oriented chromophores. In certain embodiments, the terminal chromophore may be oriented using an external perturbation such as, for example, an electric field, by trapping in a matrix, by covalent bonding to a matrix, using a viscous medium, using an additive such as, for example, a liquid crystal, or any combinations of these and materials or methods.

In some examples, a first chromophore may be oriented at an angle to increase absorption of light incident on the substrate. This result may occur, for example, if the transition dipole of the first chromophore was oriented perpendicular to the incident light rays and/or parallel to the guiding direction. For example, by orienting the first chromophore at a selected angle the amount of light absorbed may be increased by 10% to about 50% or more as compared to a random orientation. The first chromophore may be oriented, for example, using an external perturbation, trapping in a matrix, covalent binding to a matrix, using an additive such as, for example, a liquid crystal or any combination of these and other materials or methods.

In certain examples, the first chromophore may be oriented or aligned independent of the second chromophore. For example, a first method may be used to orient the first chromophore and a second different method may be used to orient the second chromophore. In one illustration, the first chromophore may include one or more functional groups that can bind to a matrix, and the second chromophore may be susceptible to alignment in an electric field. In this manner, the orientation of each of the chromophores may be individually controlled to increase the overall efficiency of the device.

In other examples, the second chromophore may be oriented at an angle to increase the light-trapping efficiency. This result may occur, for example, if the transition dipole of the second chromophore was oriented parallel to the incident light rays and/or perpendicular to the guiding direction. For example, by orienting the second chromophore at a selected angle the light-trapping efficiency may be increased by 10% to about 50% or more compared to a random orientation. When an LSC comprises a first tuned chromophore for light absorption and a second tuned chromophore for light emission, the overall efficiency of the device may be increased by 25% or more as compared to a device including randomly oriented first and second chromophores.

In certain examples, the solar concentrator of the devices disclosed herein may include a substrate comprising at least first and second closely spaced chromophores disposed on or in the substrate in a manner to receive at least some optical radiation, the first chromophore effective to absorb at least one wavelength of at least some of the optical radiation and further effective to transfer at least some energy by Förster energy transfer to the second chromophore, the second chromophore effective to emit at least some of the transferred energy at a wavelength that is red-shifted from the wavelength absorbed by the first chromophore. In certain embodiments, one or both of the first and second chromophores may be tuned. In some examples, the solar concentrator may include one or more wavelength selective mirrors on a surface. In other examples, the chromophore(s) may be disposed in a polar matrix, which may trap and/or covalently bond to one or both of the first and second chromophores. The solar concentrator may be optically coupled to the PV cell to provide light to the PV cell.

In other embodiments, the solar concentrator of the devices disclosed herein may include a substrate comprising at least first and second closely spaced chromophores disposed on or in the substrate in a manner to receive optical radiation, the first chromophore effective to absorb at least some optical radiation and to transfer at least some energy to the second chromophore, the second chromophore effective to emit at least some of the transferred energy at a wavelength that is red-shifted from a wavelength of optical radiation absorbed by the first chromophore, in which the first chromophore is present at a concentration at least ten times greater than the concentration of the second chromophore. In certain examples, one or both of the first and second chromophores may be tuned chromophores. In some examples, the solar concentrator may include one or more wavelength selective mirrors on a surface. In other examples, the chromophore(s) may be disposed in a polar matrix, which may trap and/or covalently bond to one or both of the chromophores. The solar concentrator may be optically coupled to the PV cell to provide light to the PV cell.

In additional embodiments, the solar concentrator of the devices disclosed herein may include a substrate comprising a plurality of chromophores disposed on or in the substrate in a manner to receive optical radiation, the plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores. In certain examples, one or more of the chromophores may be tuned chromophores. In some examples, the solar concentrator may include one or more wavelength selective mirrors on a surface. In other examples, the chromophore(s) may be disposed in a polar matrix, which may trap and/or covalently bond to one or more of the chromophores. The solar concentrator may be optically coupled to the PV cell to provide light to the PV cell.

In some examples, the solar concentrator of the devices disclosed herein may include a substrate comprising a film disposed on the substrate in a manner to receive at least some optical radiation, the film comprising at least a first chromophore and a second chromophore, the first chromophore effective to absorb at least one wavelength of at least some of the optical radiation and further effective to transfer at least some of the energy by Förster energy transfer to the second chromophore, the second chromophore effective to emit at least some of the transferred energy at a wavelength that is red-shifted from the wavelength absorbed by the first chromophore. In certain examples, one or both of the first and second chromophores may be a tuned chromophore. In some examples, the solar concentrator may include one or more wavelength selective mirrors on a surface. In other examples, the first chromophore may be disposed in a polar matrix, which may trap and/or covalently bond to one or both of the first and second chromophores. The solar concentrator may be optically coupled to the PV cell to provide light to the PV cell.

In certain embodiments, the solar concentrator of the devices disclosed herein may include a substrate comprising a film disposed on the substrate in a manner to receive at least some optical radiation, the film comprising a plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores. In certain examples, one or more of the chromophores may be a tuned chromophore. In some examples, the solar concentrator may include one or more wavelength selective mirrors on a surface. In other examples, the chromophore(s) may be disposed in a polar matrix, which may trap and/or covalently bond to one or more of the chromophores. The solar concentrator may be optically coupled to the PV cell to provide light to the PV cell.

In some embodiments, the solar concentrator of the devices disclosed herein may include a substrate comprising a film disposed on the substrate in a manner to receive at least some optical radiation, the film comprising at least a first chromophore and a second chromophore, the first chromophore effective to absorb at least some optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present in the film at a concentration at least ten times greater than the concentration of the second chromophore in the film. In certain examples, one or both of the first and second chromophores may be tuned chromophores. In some examples, the solar concentrator may include one or more wavelength selective mirrors on a surface. In other examples, the first chromophore may be disposed in a polar matrix, which may trap and/or covalently bond to one or both of the first and second chromophores. The solar concentrator may be optically coupled to the PV cell to provide light to the PV cell.

In certain examples, the solar concentrator of the devices disclosed herein may include a substrate comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In certain embodiments, the material may be tuned. In some examples, the solar concentrator may include one or more wavelength selective mirrors on a surface. In other examples, the material may be disposed in a polar matrix, which may trap and/or covalently bond to the material. The solar concentrator may be optically coupled to the PV cell to provide light to the PV cell.

In some embodiments, the solar concentrator of the devices disclosed herein may include a substrate comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to higher wavelengths such that the first and second wavelength ranges do not substantially overlap in wavelength. In certain examples, the material or the red-shifting agent may be tuned. In some examples, the solar concentrator may include one or more wavelength selective mirrors on a surface. In other examples, the material may be disposed in a polar matrix, which may trap and/or covalently bond to one or both of the material and the red-shifting agent. The solar concentrator may be optically coupled to the PV cell to provide light to the PV cell.

In other examples, the solar concentrator of the devices disclosed herein may include a substrate comprising a composition disposed on or in the substrate in a manner to absorb at least some optical radiation, the composition comprising at least one porphyrin compound. In certain examples, the porphyrin compound may be tuned. In some examples, the solar concentrator may include one or more wavelength selective mirrors on a surface. In other examples, the porphyrin compound may be disposed in a polar matrix, which may trap and/or covalently bond to the porphyrin compound. The solar concentrator may be optically coupled to the PV cell to provide light to the PV cell.

In additional embodiments, the solar concentrator of the devices disclosed herein may include a substrate comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In some examples, the porphyrin compound may be tuned as described herein. In certain examples, the solar concentrator may include one or more wavelength selective mirrors on a surface. In other examples, the porphyrin compound may be disposed in a polar matrix, which may trap and/or covalently bond to the porphyrin compound. The solar concentrator may be optically coupled to the PV cell to provide light to the PV cell.

In certain embodiments, the solar concentrator of the devices disclosed herein may include a substrate comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In certain examples, the porphyrin compound, the red-shifting agent or both may be tuned. The solar concentrator may be optically coupled to the PV cell to provide light to the PV cell.

In some embodiments, the solar concentrator of the devices disclosed herein may include a substrate comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the porphyrin compound to shift the second wavelength range to a higher wavelength range such that the first and second wavelength ranges do not substantially overlap in wavelength. In certain examples, the porphyrin compound, the red-shifting agent or both may be tuned, as described herein. In some examples, the solar concentrator may include one or more wavelength selective mirrors on a surface. In other examples, the porphyrin compound and/or the red-shifting agent may be disposed in a polar matrix, which may trap and/or covalently bond to one or both of the porphyrin compound and/or the red-shifting agent. The solar concentrator may be optically coupled to the PV cell to provide light to the PV cell.

In certain examples, the solar concentrator of the devices disclosed herein may include a substrate comprising a composition disposed on or in the substrate in a manner to absorb at least some optical radiation, the composition comprising at least one organometallic compound. In certain embodiments, the organometallic compound may be tuned, as described herein. In some examples, the solar concentrator may include one or more wavelength selective mirrors on a surface. In other examples, the organometallic compound may be disposed in a polar matrix, which can trap and/or covalently bind to the organometallic compound. The solar concentrator may be optically coupled to the PV cell to provide light to the PV cell.

In some examples, the solar concentrator of the devices disclosed herein may include a substrate comprising a composition disposed on or in the substrate in a manner to absorb at least some optical radiation, the composition comprising at least one organometallic compound effective to absorb the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In certain examples, the organometallic compound may be tuned. In some examples, the solar concentrator may include one or more wavelength selective mirrors on a surface. In other examples, the organometallic compound may be disposed in a polar matrix, which can trap and/or covalently bind to the organometallic compound. The solar concentrator may be optically coupled to the PV cell to provide light to the PV cell.

In certain embodiments, the solar concentrator of the devices disclosed herein may include a substrate comprising a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In certain examples, the organometallic compound and/or the red-shifting agent may be tuned. In some examples, the solar concentrator may include one or more wavelength selective mirrors on a surface. In other examples, the organometallic compound and/or the red-shifting agent may be disposed in a polar matrix, which can trap and/or covalently bind to the organometallic compound and/or the red-shifting agent. The solar concentrator may be optically coupled to the PV cell to provide light to the PV cell.

In some embodiments, the solar concentrator of the devices disclosed herein may include a substrate comprising a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the organometallic compound to shift the second wavelength range to a higher wavelength range such that the first and second wavelength ranges do not substantially overlap in wavelength. In certain examples, the red-shifting agent-organometallic complex can be tuned. In some examples, the solar concentrator may include one or more wavelength selective mirrors on a surface. In other examples, the organometallic compound may be disposed in a polar matrix, which can trap and/or covalently bind to the organometallic compound-red shifting agent complex. The solar concentrator may be optically coupled to the PV cell to provide light to the PV cell.

In certain examples, the solar concentrator of the devices disclosed herein may include a substrate having a refractive index of greater than or equal to 1.7 and comprising a chromophore disposed on or in the substrate and effective to absorb optical radiation. In certain embodiments, the chromophore may be tuned. In some examples, the solar concentrator may include one or more wavelength selective mirrors on a surface. In other examples, the chromophore may be disposed in a polar matrix, which can trap and/or covalently bind to the chromophore. The solar concentrator may be optically coupled to the PV cell to provide light to the PV cell.

In some examples, the solar concentrator of the devices disclosed herein may include a substrate having a refractive index of greater than or equal to 1.7 and comprising at least first and second closely spaced chromophores disposed on or in the substrate in a manner to receive at least some optical radiation, the first chromophore effective to absorb at least one wavelength of at least some of the optical radiation and arranged to transfer at least some energy by Förster energy transfer to the second chromophore, the second chromophore effective to emit at least some of the transferred energy at a wavelength that is red-shifted from the wavelength absorbed by the first chromophore. In certain examples, at least one of the chromophores may be tuned. In some examples, the solar concentrator may include one or more wavelength selective mirrors on a surface. In other examples, the chromophore(s) may be disposed in a polar matrix, which can trap and/or covalently bind to one or more of the chromophores. The solar concentrator may be optically coupled to the PV cell to provide light to the PV cell.

In certain embodiments, the solar concentrator of the devices disclosed herein may include a substrate having a refractive index of greater than or equal to 1.7 and comprising a plurality of chromophores disposed on or in the substrate in a manner to receive at least some optical radiation, the plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores. In certain examples, at least one of the chromophores may be tuned. In some examples, the solar concentrator may include one or more wavelength selective mirrors on a surface. In other examples, the chromophore(s) may be disposed in a polar matrix, which can trap and/or covalently bind to one or more of the chromophores. The solar concentrator may be optically coupled to the PV cell to provide light to the PV cell.

In some examples, the solar concentrator of the devices disclosed herein may include a substrate having a refractive index of greater than or equal to 1.7 and comprising at least first and second closely spaced chromophores disposed on or in the substrate in a manner to receive at least some optical radiation, the first chromophore effective to absorb at least some optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present at a concentration at least ten times greater than the concentration of the second chromophore. In certain embodiments, at least one of the chromophores may be tuned. In some examples, the solar concentrator may include one or more wavelength selective mirrors on a surface. In other examples, the chromophore(s) may be disposed in a polar matrix, which can trap and/or covalently bind to at least one of the chromophores. The solar concentrator may be optically coupled to the PV cell to provide light to the PV cell.

In certain embodiments, the solar concentrator of the devices disclosed herein may include a substrate having a refractive index of at least about 1.7 and comprising a film disposed on the substrate in a manner to receive optical radiation, the film comprising at least a first chromophore and a second chromophore, the first chromophore effective to absorb at least one wavelength of at least some of the optical radiation and arranged to transfer at least some energy by Förster energy transfer to the second chromophore, the second chromophore effective to emit at least some of the transferred energy at a wavelength that is red-shifted from the wavelength absorbed by the first chromophore. In certain examples, at least one of the first and second chromophores may be tuned. In some examples, the solar concentrator may include one or more wavelength selective mirrors on a surface. In other examples, the chromophore(s) may be disposed in a polar matrix, which can trap and/or covalently bind to one or both of the first and second chromophores. The solar concentrator may be optically coupled to the PV cell to provide light to the PV cell.

In certain examples, the solar concentrator of the devices disclosed herein may include a substrate having a refractive index of greater than or equal to 1.7 and comprising a film disposed on the substrate in a manner to receive at least some optical radiation, the film comprising a plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore effective to emit at least some of the received energy at a wavelength that is red-shifted from the at least one wavelength absorbed by the plurality of chromophores. In certain embodiments, at least one of the chromophores may be tuned. In some examples, the solar concentrator may include one or more wavelength selective mirrors on a surface. In other examples, the chromophore(s) may be disposed in a polar matrix, which can trap and/or covalently bind to at least one of the chromophores. The solar concentrator may be optically coupled to the PV cell to provide light to the PV cell.

In some examples, the solar concentrator of the devices disclosed herein may include a substrate having a refractive index of greater than or equal to 1.7 and comprising a film disposed on the substrate in a manner to receive at least some optical radiation, the film comprising at least a first chromophore and a second chromophore, the first chromophore effective to absorb at least some optical radiation and transfer at least some of the energy to the second chromophore, the second chromophore effective to emit at least some of the transferred energy at a wavelength that is red-shifted from a wavelength of optical radiation absorbed by the first chromophore, in which the first chromophore is present in the film in a concentration at least ten times greater than the concentration of the second chromophore in the film. In certain embodiments, at least one of the first and second chromophores may be tuned. In some examples, the solar concentrator may include one or more wavelength selective mirrors on a surface. In other examples, the chromophore(s) may be disposed in a polar matrix, which can trap and/or covalently bind to one or more of the chromophores. The solar concentrator may be optically coupled to the PV cell to provide light to the PV cell.

In certain embodiments, the solar concentrator of the devices disclosed herein may include a substrate having a refractive index of greater than or equal to 1.7 and comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In certain examples, the material may be tuned. In some examples, the solar concentrator may include one or more wavelength selective mirrors on a surface. In other examples, the material may be disposed in a polar matrix, which can trap and/or covalently bind to the material. The solar concentrator may be optically coupled to the PV cell to provide light to the PV cell.

In some examples, the solar concentrator of the devices disclosed herein may include a substrate having a refractive index of greater than or equal to 1.7 and comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In certain examples, the material may be tuned. In some examples, the material may include one or more wavelength selective mirrors on a surface. In other examples, the chromophore(s) may be disposed in a polar matrix, which can trap and/or covalently bind to the material. The solar concentrator may be optically coupled to the PV cell to provide light to the PV cell.

In certain embodiments, the solar concentrator of the devices disclosed herein may include a substrate having a refractive index of greater than or equal to 1.7 and comprising a composition disposed on or in the substrate in a manner to absorb at least some optical radiation, the composition comprising at least one porphyrin compound. In certain embodiments, the porphyrin compound may be tuned. In some examples, the solar concentrator may include one or more wavelength selective mirrors on a surface. In other examples, the porphyrin compound may be disposed in a polar matrix, which can trap and/or covalently bind to the porphyrin compound. The solar concentrator may be optically coupled to the PV cell to provide light to the PV cell.

In some examples, the solar concentrator of the devices disclosed herein may include a substrate having a refractive index of greater than or equal to 1.7 and a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In certain examples, the porphyrin compound may be tuned. In some examples, the solar concentrator may include one or more wavelength selective mirrors on a surface. In other examples, the porphyrin compound may be disposed in a polar matrix, which can trap and/or covalently bind to the porphyrin compound. The solar concentrator may be optically coupled to the PV cell to provide light to the PV cell.

In additional examples, the solar concentrator of the devices disclosed herein may include a substrate having a refractive index of greater than or equal to 1.7 and comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In certain examples, the porphyrin compound may be tuned. In some examples, the solar concentrator may include one or more wavelength selective mirrors on a surface. In other examples, the porphyrin compound may be disposed in a polar matrix, which can trap and/or covalently bind to the porphryin compound. The solar concentrator may be optically coupled to the PV cell to provide light to the PV cell.

In certain embodiments, the solar concentrator of the devices disclosed herein may include a substrate having a refractive index of greater than or equal to 1.7 and comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the porphyrin compound to shift the second wavelength range to a higher wavelength range such that the first and second wavelength ranges do not substantially overlap in wavelength. In certain examples, the porphryin compound, the red-shifting agent or both may be tuned. In some examples, the solar concentrator may include one or more wavelength selective mirrors on a surface. In other examples, the porphyrin compound and/or red-shifting agent may be disposed in a polar matrix, which can trap and/or covalently bind to the porphyrin compound and/or red-shifting agent. The solar concentrator may be optically coupled to the PV cell to provide light to the PV cell.

In some examples, the solar concentrator of the devices disclosed herein may include a substrate having a refractive index of greater than or equal to 1.7 and comprising a composition disposed on or in the substrate in a manner to absorb at least some optical radiation, the composition comprising at least one organometallic compound. In certain embodiments, the organometallic compound may be tuned. In some examples, the solar concentrator may include one or more wavelength selective mirrors on a surface. In other examples, the organometallic compound may be disposed in a polar matrix, which can trap and/or covalently bind to the organometallic compound. The solar concentrator may be optically coupled to the PV cell to provide light to the PV cell.

In certain examples, the solar concentrator of the devices disclosed herein may include a substrate having a refractive index of greater than or equal to 1.7 and a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In certain embodiments, the organometallic compound may be tuned. In some examples, the solar concentrator may include one or more wavelength selective mirrors on a surface. In other examples, the organometallic compound may be disposed in a polar matrix, which can trap and/or covalently bind to the organometallic compound. The solar concentrator may be optically coupled to the PV cell to provide light to the PV cell.

In some embodiments, the solar concentrator of the devices disclosed herein may include a substrate having a refractive index of greater than or equal to 1.7 and comprising a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In certain examples, the organometallic compound and/or red-shifting agent may be tuned. In some examples, the solar concentrator may include one or more wavelength selective mirrors on a surface. In other examples, the organometallic compound and/or red-shifting agent may be disposed in a polar matrix, which can trap and/or covalently bind to the organometallic compound and/or the red-shifting agent. The solar concentrator may be optically coupled to the PV cell to provide light to the PV cell.

In certain examples, the solar concentrator of the devices disclosed herein may include a substrate having a refractive index of greater than or equal to 1.7 and comprising a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the organometallic compound to shift the second wavelength range to a higher wavelength range such that the first and second wavelength ranges do not substantially overlap in wavelength. In certain embodiments, the organometallic compound-red-shifting agent complex may be tuned. In some examples, the solar concentrator may include one or more wavelength selective mirrors on a surface. In other examples, the organometallic compound-red-shifting agent complex may be disposed in a polar matrix, which can trap and/or covalently bind to the organometallic compound-red-shifting agent complex. The solar concentrator may be optically coupled to the PV cell to provide light to the PV cell.

In some embodiments, the solar concentrator of the devices disclosed herein may include a substrate configured to trap at least 80% of the quanta of radiation incident on the substrate and a chromophore disposed on or in the substrate and effective to absorb at least some optical radiation and emit at least some of the absorbed optical radiation at a longer wavelength. In certain examples, the chromophore may be tuned. In some examples, the solar concentrator may include one or more wavelength selective mirrors on a surface. In other examples, the chromophore may be disposed in a polar matrix, which can trap and/or covalently bind to the chromophore. The solar concentrator may be optically coupled to the PV cell to provide light to the PV cell.

In certain embodiments, the solar concentrator of the devices disclosed herein may include a substrate configured to trap at least 80% of the quanta of radiation incident on the substrate and comprising at least first and second closely spaced chromophores disposed on or in the substrate in a manner to receive at least some optical radiation, the first chromophore effective to absorb at least one wavelength of at least some of the optical radiation and further effective to transfer at least some energy by Förster energy transfer to the second chromophore, the second chromophore effective to emit at least some of the transferred energy at a wavelength that is red-shifted from the wavelength absorbed by the first chromophore. In certain examples, at least one of the first and second chromophores can be tuned. In some examples, the solar concentrator may include one or more wavelength selective mirrors on a surface. In other examples, the chromophore(s) may be disposed in a polar matrix, which can trap and/or covalently bind to one or more of the chromophores. The solar concentrator may be optically coupled to a PV cell to provide light to the PV cell.

In some examples, the solar concentrator of the devices disclosed herein may include a substrate configured to trap at least 80% of the quanta of radiation incident on the substrate and comprising at least first and second closely spaced chromophores disposed on or in the substrate in a manner to receive at least some optical radiation, the first chromophore effective to absorb at least some of the optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present in a concentration at least ten times greater than the concentration of the second chromophore. In certain examples, at least one of the chromophores may be tuned. In some examples, the solar concentrator may include one or more wavelength selective mirrors on a surface. In other examples, the chromophore(s) may be disposed in a polar matrix, which can trap and/or covalently bind to one or more of the chromophores. The solar concentrator may be optically coupled to a PV cell to provide light to the PV cell.

In certain embodiments, the solar concentrator of the devices disclosed herein may include a substrate configured to trap at least 80% of the quanta of radiation incident on the substrate and comprising at least first and second closely spaced chromophores disposed on the substrate in a manner to receive at least some optical radiation, the first chromophore effective to absorb at least some of the optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present at a concentration at least ten times greater than the concentration of the second chromophore. In certain examples, one or both of the chromophores may be tuned. In some examples, the solar concentrator may include one or more wavelength selective mirrors on a surface. In other examples, the chromophore(s) may be disposed in a polar matrix, which can trap and/or covalently bind to one or more of the chromophores. The solar concentrator may be optically coupled to a PV cell to provide light to the PV cell.

In certain examples, the solar concentrator of the devices disclosed herein may include a substrate configured to trap at least 80% of the quanta of radiation incident on the substrate and comprising a film disposed on the substrate in a manner to receive at least some optical radiation, the film comprising at least a first chromophore and a second chromophore, the first chromophore effective to absorb at least one wavelength of at least some of the optical radiation and arranged to transfer at least some energy by Förster energy transfer to the second chromophore, the second chromophore effective to emit at least some of the transferred energy at a wavelength that is red-shifted from the wavelength absorbed by the first chromophore. In certain embodiments, one or both of the first and second chromophores may be tuned. In some examples, the solar concentrator may include one or more wavelength selective mirrors on a surface. In other examples, the chromophore(s) may be disposed in a polar matrix, which can trap and/or covalently bind to one or more of the chromophores. The solar concentrator may be optically coupled to a PV cell to provide light to the PV cell.

In other examples, the solar concentrator of the devices disclosed herein may include a substrate configured to trap at least 80% of the quanta of radiation incident on the substrate and comprising a film disposed on the substrate in a manner to receive at least some optical radiation, the film comprising a plurality of chromophores each effective to absorb at least one wavelength of at least some of the optical radiation without substantial light emission of the absorbed optical radiation, the film further comprising a terminal chromophore effective to receive at least some of the absorbed radiation from the plurality of chromophores, the terminal chromophore further effective to emit at least some of the received energy at a wavelength that is red-shifted from the at least one wavelength absorbed by the plurality of chromophores. In certain examples, one or more of the chromophores may be tuned. In some examples, the solar concentrator may include one or more wavelength selective mirrors on a surface. In other examples, the chromophore(s) may be disposed in a polar matrix, which can trap and/or covalently bind to one or more of the chromophores. The solar concentrator may be optically coupled to a PV cell to provide light to the PV cell.

In certain embodiments, the solar concentrator of the devices disclosed herein may include a substrate configured to trap at least 80% of the quanta of radiation incident on the substrate and comprising a film disposed on the substrate in a manner to receive at least some optical radiation, the film comprising at least a first chromophore and a second chromophore, the first chromophore effective to absorb at least some of the optical radiation and transfer at least some energy to the second chromophore, the second chromophore effective to emit at least some of the transferred energy at a wavelength that is red-shifted from a wavelength of optical radiation absorbed by the first chromophore, in which the first chromophore is present in the film in a concentration at least ten times greater than the concentration of the second chromophore in the film. In certain examples, one or more of the chromophores may be tuned. In some examples, the solar concentrator may include one or more wavelength selective mirrors on a surface. In other examples, the chromophore(s) may be disposed in a polar matrix, which can trap and/or covalently bind to one or more of the chromophores. The solar concentrator may be optically coupled to a PV cell to provide light to the PV cell.

In some embodiments, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In certain examples, the material may be tuned. In some examples, the solar concentrator may include one or more wavelength selective mirrors on a surface. In other examples, the material may be disposed in a polar matrix, which can trap and/or covalently bind to the material. The solar concentrator may be optically coupled to a PV cell to provide light to the PV cell.

In additional examples, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising a material effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to higher wavelengths such that the first and second wavelength ranges do not substantially overlap in wavelength. In certain examples, the material and/or red-shifting agent may be tuned. In some examples, the solar concentrator may include one or more wavelength selective mirrors on a surface. In other examples, the material may be disposed in a polar matrix, which can trap and/or covalently bind to the material and/or red-shifting agent. The solar concentrator may be optically coupled to a PV cell to provide light to the PV cell.

In some examples, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising at least one porphyrin compound. In certain examples, the porphyrin compound may be tuned. In some examples, the solar concentrator may include one or more wavelength selective mirrors on a surface. In other examples, the porphyrin compound may be disposed in a polar matrix, which can trap and/or covalently bind to the porphyrin compound. The solar concentrator may be optically coupled to a PV cell to provide light to the PV cell.

In certain examples, the solar concentrator of the devices disclosed herein may include a substrate configured to trap at least 80% of the quanta of radiation incident on the substrate and a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In certain embodiments, the porphyrin compound may be tuned. In some examples, the solar concentrator may include one or more wavelength selective mirrors on a surface. In other examples, the porphyrin compound may be disposed in a polar matrix, which can trap and/or covalently bind to the porphryin compound. The solar concentrator may be optically coupled to a PV cell to provide light to the PV cell.

In certain embodiments, the solar concentrator of the devices disclosed herein may include a substrate configured to trap at least 80% of the quanta of radiation emitted in the substrate and comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to a higher wavelength range such that the first and second wavelength ranges do not substantially overlap in wavelength. In certain examples, the porphyrin compound may be tuned. In some examples, the solar concentrator may include one or more wavelength selective mirrors on a surface. In other examples, the porphyrin compound may be disposed in a polar matrix, which can trap and/or covalently bind to the porphyrin compound. The solar concentrator may be optically coupled to a PV cell to provide light to the PV cell.

In some examples, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising at least one porphyrin compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the porphyrin compound to shift the second wavelength range to a higher wavelength range such that the first and second wavelength ranges do not substantially overlap in wavelength. In certain examples, the porphyrin compound can be tuned. In some examples, the solar concentrator may include one or more wavelength selective mirrors on a surface. In other examples, the porphyrin compound may be disposed in a polar matrix, which can trap and/or covalently bind to the porphyrin compound. The solar concentrator may be optically coupled to a PV cell to provide light to the PV cell.

In other examples, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising at least one organometallic compound. In certain examples, the organometallic compound may be tuned. In some examples, the solar concentrator may include one or more wavelength selective mirrors on a surface. In other examples, the organometallic compound may be disposed in a polar matrix, which can trap and/or covalently bind to the organometallic compound. The solar concentrator may be optically coupled to a PV cell to provide light to the PV cell.

In certain embodiments, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, in which the first and second wavelength ranges do not substantially overlap in wavelength. In certain examples, organometallic compound may be tuned. In some examples, the solar concentrator may include one or more wavelength selective mirrors on a surface. In other examples, the organometallic compound may be disposed in a polar matrix, which can trap and/or covalently bind to the organometallic compound. The solar concentrator may be optically coupled to a PV cell to provide light to the PV cell.

In some embodiments, the solar concentrator of the devices disclosed herein may include a substrate configured to trap at least 80% of the quanta of radiation incident on the substrate and comprising a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent to shift the second wavelength range to higher wavelengths such that the first and second wavelength ranges do not substantially overlap in wavelength. In certain examples, the organometallic compound and/or the red-shifting agent may be tuned. In some examples, the solar concentrator may include one or more wavelength selective mirrors on a surface. In other examples, the organometallic compound and/or red-shifting agent may be disposed in a polar matrix, which can trap and/or covalently bind to the organometallic compound and/or the red-shifting agent. The solar concentrator may be optically coupled to a PV cell to provide light to the PV cell.

In certain examples, the solar concentrator of the devices disclosed herein may include a substrate configured to trap at least 80% of the quanta of radiation incident on the substrate and a composition disposed on or in the substrate in a manner to absorb at least some optical radiation, the composition comprising at least one organometallic compound effective to absorb at least some of the optical radiation within a first wavelength range and to emit at least some of the absorbed optical radiation by phosphorescence within a second wavelength range that is red-shifted from the first wavelength range, the composition further comprising an effective amount of a red-shifting agent complexed to the organometallic compound to shift the second wavelength range to a higher wavelength range such that the first and second wavelength ranges do not substantially overlap in wavelength. In certain embodiments, the organometallic compound-red-shifting agent complex may be tuned. In some examples, the solar concentrator may include one or more wavelength selective mirrors on a surface. In other examples, the organometallic compound-red-shifting agent complex may be disposed in a polar matrix, which can trap and/or covalently bind to the organometallic compound-red-shifting agent complex. The solar concentrator may be optically coupled to a PV cell to provide light to the PV cell.

In accordance with certain examples, the solar concentrators disclosed herein may be used with many different types of PV cells and PV cells having different efficiencies. By using the solar concentrators disclosed herein, the efficiency of each PV cell need not be the same. For example, it may be desirable to use a high efficiency PV cell without a concentrator and use a low efficiency PV cell with a concentrator to provide substantially the same efficiency for each of the PV cells. In addition, it may be desirable to selectively position the PV cells in an array to utilize the different efficiencies. Electrical power losses from heating increase with increasing current flowing in a module circuit. The current is minimized with a serial configuration. For this reason, the typical configuration of individual solar cells when connected in a module is in series. For cells connected in this way, it is desirable that each cell passes the same amount of current. Otherwise, PV cells with lower currents will limit the total current that can flow through the whole module limiting the power conversion efficiency. In a typical module, effort and cost is devoted to testing and sorting individual cells such that all cells to be put into a module are as close to identical in performance as possible. Also, they are typically all the same size. The light intensity reaching the edges of a luminescent solar concentrator (LSC) depends on position on the guide. Since the light intensity depends on position, the current passing through each solar cell should also depend on position. If identical PV cells are used (either in size or performance), the module power conversion efficiency will be limited by the cell receiving the least light and thus passing the least current.

In accordance with certain examples, the geometry of the PV cell may also be tailored or designed such that PV cells having different efficiencies may be used with one or more of the solar concentrators disclosed herein. For example, the amount of light reaching each of the collection edges depends, ay least in part, on waveguide geometry. For manufacturing simplicity and cost, many solar concentrators may be produced in rectangular or square configurations, but other geometries are possible. For a simple rectangular case, the light reaching the corners will be lower than those edges closest to the center as optical losses increase with the distance light travels in the waveguide. By adjusting the PV cell efficiency as a function of position, higher efficiency cells can be used in the edges near the corners and lower efficiency cells can be used in the edges near the solar concentrator center. Using this arrangement, the current flowing through each PV cell may be substantially equal and module efficiency is not limited by lower current PV cells. This arrangement permits for the use of cells of variable performance efficiencies instead of using the lower efficiency cells in less valuable lower efficiency modules. In addition, the chromophores may be tuned such that light is preferentially emitted in one direction to increase the overall efficiency of the device.

In certain examples, the dimension of the PV cells may also be adjusted to provide similar efficiencies. For example, by adjusting the cell dimensions of identically efficient cells, similar current matching is possible. If all cell heights are identical (set, for example, by the edge thickness), then the cell lengths may be altered to accommodate the differing light intensities as a function of position. PV cells at the edges closest to the corners may be longer, and cells at the edges closest to the concentrator center may be shorter. The use of such variable size PV cells with the concentrators disclosed herein provides similar efficiencies to increase the overall efficiency of a solar cell array.

In accordance with certain examples, the various materials used in the concentrators disclosed herein, e.g., chromophores, red-shifting agents, thin films, etc., may be disposed using numerous different methods including, but not limited to, painting, brushing, spin coating, casting, molding, sputtering, vapor deposition (e.g., physical vapor deposition, chemical vapor deposition and the like), plasma enhanced vapor deposition, pulsed laser deposition and the like. In some examples, organic vapor phase deposition (OVPD) may be used to deposit at least one of the components of the solar concentrators disclosed herein. OVPD may be used, for example, to dispose or coat a waveguide with one or more chromophores, red-shifting agents, heavy metals or the like. In some examples, OVPD may be used to produce a solar concentrator by disposing a vapor phase of the chromophore on a substrate and optionally curing or heating the substrate. Illustrative devices for OVPD are commercially available, for example, from Aixtron (Germany). Suitable methods, parameters and devices for OVPD are described, for example in Baldo et al., Appl. Phys. Lett. 71(2), 3033-3035, 1997. Where a matrix is used, the matrix may be deposited using similar methods. Also, the matrix may be cross-linked using an oven, heat gun, laser or other suitable devices depending on the exact composition and properties of the matrix.

In accordance with certain examples, a high index epoxy or adhesive may be used to attach the solar concentrators disclosed herein to a PV cell. For example, solar cells may be produced using a high index adhesive or epoxy such that index mismatching may be avoided or substantially reduced. In one illustration, to reduce the light coupling losses, it may be desirable to reduce optical reflections as light passes from the LSC into the PV cell. There may be an index mismatch between the waveguide and the solar cell, but this mismatch need not introduce large reflections if the solar cell is covered by an antireflection coating (most solar cells have them built into their structure). These antireflection coatings may be designed for light that is incident from air but can be redesigned for light that is incident from a solar concentrator. If the PV cells are attached to the LSC by an epoxy or an adhesive, the epoxy or adhesive may introduce unwanted reflections, and the thickness of the epoxy or adhesive may be difficult to control. By using epoxies which are index-matched to the waveguide, the antireflection coating of the solar cell may be designed for light incident from the waveguide and the exact thickness of the epoxy or adhesive is less important. Thus, by using an epoxy or adhesive whose index is matched to the substrate or waveguide, the overall efficiency of a solar cell may be increased.

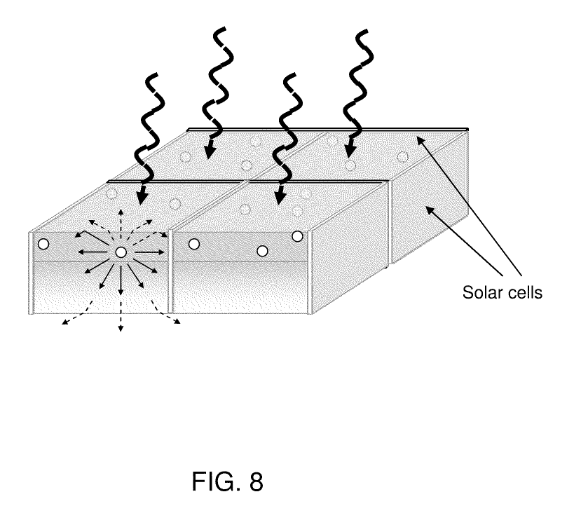

In accordance with certain examples, the PV cells may be embedded or otherwise integrated into the solar concentrators disclosed herein. For example, where the substrate is producing using one or more polymers, e.g., a plastic, it may be desirable to embed the PV cell into the waveguide rather than attach the PV cell at an edge of the waveguide. A configuration of such embedded PV cell is shown in FIG. 8. In embodiments where the concentrator is produced using a plastic, the PV cell can be embedded in the plastic melt when the liquid material is cast or injection molded. This process permits omission of any epoxy or adhesive joints to attach a PV cell to the solar concentrator. As the joints are been removed, the index matching to a substrate is not required, and the antireflection coating on the PV cell may be designed directly for light incident from the waveguide. In addition, in a solar concentrator that is limited in geometric optical gain by re-absorption losses, very large modules can be made with lower optical gains. For example, a chromophore may limit the concentration factor to 100, e.g., corresponding to waveguide dimensions of 80 cm×80 cm×2 mm. If a module with larger dimension is desired, e.g., 160 cm×160 cm×2 mm, four concentrators would be tiled in an array inside the module. This design constraint may be avoided by embedding the PV cells in a grid within the solar concentrator, so the module can be made larger without sacrificing performance due to chromophore re-absorption.

In accordance with certain examples, the solar cell devices disclosed herein may be arranged with other solar cell devices disclosed herein to provide an array of solar cells. For example, the system may comprise a plurality of photovoltaic cells constructed and arranged to receive optical radiation from the sun, wherein at least one of the plurality of photovoltaic cells is coupled to a solar concentrator as described herein. In particular, the solar concentrator of the system may be any one or more of the solar concentrator disclosed herein. In addition, the system may include a plurality of solar concentrators with each of the solar concentrators being the same type of solar concentrator. In other examples, many different types of solar concentrators may be present in the system.

In accordance with certain examples, methods of increasing the efficiency of a PV cell are disclosed. In certain examples, the method comprises providing concentrated optical radiation to a photovoltaic cell from a solar concentrator, the solar concentrator comprising any of the solar concentrators disclosed herein. In other examples, the method may further include embedding the PV cells in the solar concentrators to further increase the efficiency of the PV cells. Other methods of using the solar concentrators disclosed herein to increase the efficiency of PV cells and systems including PV cells will be readily selected by the person of ordinary skill in the art, given the benefit of this disclosure.

In accordance with certain examples, two or more waveguides may be optically coupled such that one of the waveguides absorbs light within a first wavelength range and at least one of the other waveguides absorbs light within a second wavelength range different from the first wavelength range. Devices that include two or more waveguides are referred to in certain instances herein as tandem devices. The tandem device may include two solar concentrators as described herein or may include a solar concentrator coupled to an existing thin film photovoltaic cell. Converting light to electrical current with multiple electrical bandgaps in a tandem configuration allows a higher fraction of the lights optical power to be converted to electrical power. In a tandem device comprised of a top system comprised of a concentrator collecting light to be converted at a high bandgap solar cell and a bottom system comprised of a lower electrical bandgap thin film photovoltaic, the requirements of current matching are alleviated as the two systems no longer need to be connected serially. In a serial configuration, the currents desirably match or the cell with the lowest current can limit the overall current and thus overall efficiency of the device.

In the configuration where the top solar cell is replaced by a top LSC, current matching is not necessary as electrodes are not shared. The LSC may be attached or otherwise coupled to one or more solar cells with a selected bandgap so a greater fraction of each photon's power will be extracted. Finally, the light that escapes the LSC from the bottom may still be captured and converted by the lower solar cell, so the losses in the LSC will be partially diminished. The combination of an LSC with a thin film solar cell provides numerous advantages including, but not limited to, a cheaper method to improve the module efficiency compared to just the underlying solar cell alone.

In certain examples, numerous different types of solar cells may be used with an LSC to provide a tandem device, and the exact type and nature of the solar cell is not critical. Illustrative solar cells for use with a LSC in a tandem device include, but are not limited to, chalcopyrite based (CuInSe₂, CuInS₂, CuGaSe₂), cadmium telluride (CdTe) amorphous, nanocrystalline, polycrystalline, or multicrystalline silicon, and amorphous silicon-germanium (SiGe) or germanium (Ge). The LSC may be used with any one or more of the LSC's described herein. In some examples, the LSC may be used with two or more thin film PV cells, whereas in some examples two or more LSC's may be used with a single thin film PV cell. Other combinations of LSC's and thin film PV cells to provide a tandem device will be readily selected by the person of ordinary skill in the art, given the benefit of this disclosure.

In certain examples, the solar concentrators described herein may be used in or with a portable device. Portable devices are those devices that may be placed or moved by a user with ease and typically function using direct current from a battery or fuel cell source. For example, widely distributed sensors, mobile electronics, and communication and entertainment appliances are used in applications that require wireless operability. Battery power is often a convenient method for provided portability and wireless use. However, electrochemical storage devices require periodic replacement or recharging, which can be expensive and time consuming. Micropower generation, or the transduction of ambient energy sources from the local environment, offers an attractive route to complete battery replacement and/or decrease in the frequency of battery recharging cycles. Exploiting renewable energy resources in the device's environment, however, offers a power source limited by the device's physical survival rather than an adjunct energy store.

Recent motivation in environmental energy harvesting and energy scavenging has increased as low-power electronics, wireless standards, and miniaturization are increasingly prevalent in the form of sensor networks and mobile devices. Devices that experience a wide range of environmental conditions due to spatially and temporally diverse usage patterns require access to distributed energy sources and a relatively invariant power conversion efficiency dependence on energy intensity. Photovoltaic devices are one method to scavenge energy from local light sources, either in the outdoors from the sun or indoors from engineered light sources.

For portable electronics, the cost-per-area considerations are secondary, as most devices have small areas of exposed surface. To either power the devices in the steady state or contribute to a substantial extension of device lifetime, the photovoltaic devices generally are 1) used in high illumination conditions, 2) possess high power conversion efficiency, or 3) both. Additionally, true device portability is enhanced if the conversion efficiency is independent on illumination intensity and the direction of the light source(s). Existing photovoltaic devices can exhibit a strong dependence of conversion efficiency on local illumination conditions. These traits are undesirable for use in both outdoor conditions (ambient intensity 100 mW/cm²) and indoor lighting (ambient intensity 1-10 mW/cm²). In addition, photovoltaic devices made from crystalline semiconductors can exhibit a strong dependence of absorption efficiency on illumination direction. The substitution of photovoltaic devices with passive optical elements that redirect light, known as concentration, is a general method to increase the intensity of light incident on the device. Due to the logarithmic dependence of photovoltage with light intensity, optical concentration also typically results in higher power conversion. Accordingly, any one or more of the solar concentrators described herein may be electrically coupled to a photovoltaic cell and the overall assembly may be electrically coupled to the portable device to provide primary power, charging power or backup power to the portable device.

In certain embodiment, the solar concentrators described herein, when used in combination with a portable device, can provide significant advantageous characteristics including, but not limited to, (1) compatibility with both diffuse and direct illumination; the relative ratio of direct and diffuse light illumination is substantially higher for indoor versus outdoor environments; conventional photovoltaics are designed for maximal solar conversion efficiency and thus undergo significant performance degradation under purely diffuse lighting conditions; in these systems, the distribution of light absorption within the device thickness strongly affects electrical conversion efficiency (the spectral quantum efficiency varies with wavelength); in LSCs, the physical depth of the light absorption event does not affect light collection efficiency and thus can convert light with higher efficiency; (2) compatibility with diffuse light collection also allows simultaneous conversion of light absorbed over multiple collector faces; in a planar configuration, LSCs can concentrate light incident on both front and back sides of its large area faces; (3) increased optical intensity at the solar cells will increase electrical output compared to non-concentrated configurations; in addition, the lower ambient light intensity will not, when optically concentrated, overheat the solar cell, allowing passive thermal management to be employed; since each photon undergoes a bathochromic shift subsequent to absorption and preceding emission, extra energy is removed from the concentrated light that would otherwise contribute to heating potential conversion efficiency degradation; (4) for the portability of usage required of mobile electronics, it is desirable to achieve high conversion efficiencies when used under low lighting conditions (indoors), as a substantial fraction of use corresponds to these conditions. Incandescent bulbs are designed to match the spectral distribution of the sun; however, fluorescent bulbs are partly more efficient because they do not emit as much light in the infrared spectrum; as such, fluorescent indoor lighting contains a larger portion of its light spectrum within the visible band; low bandgap solar cells like silicon, cadmium telluride, and copper indium gallium selenide (1-1.4 eV) are ill-suited to extract high power from each photon since their bandgaps fall within the infrared—they are designed for sunlight. Solar cells with bandgaps in the visible frequencies enable higher electrical efficiencies as thermalization losses are reduced; put another way, the semiconductor bandgap(s) of single or multijunction solar cells that correspond to maximal power conversion efficiency for light incident from fluorescent bulbs are within the visible band instead of within the infrared band. LSCs can be designed to concentrate light at higher energies than that corresponding to the bandgap for optimal power conversion efficiency of outdoor light (about 1.1-1.3 V); as such, they can exhibit high conversion efficiencies when operating in indoor environments; (5) for devices where aesthetic appearance is important, the uniform (homogenous, or un-patterned) frontal appearance of LSCs possesses strong market advantages in segments where consumers value visual structure; in addition, the color of a LOC can be tailored at the time of manufacture, enabling visual customization, a substantial value in markets driven by aesthetic appearance, like personal entertainment, communication, and management devices.

Illustrative mobile devices that utilize batteries that can be either replaced, have their operational lifetime increased, or otherwise reduced in size, include but are not limited to: digital audio players (MP3, or “MPEG Layer-3”, or “Moving Picture Experts Group Layer 3” players), mobile phones (“cell phones” and portable phones), personal digital assistants (PDAs), portable computers (laptop computers), image sensors, cameras, mobile environmental sensors (for instance: audio, thermal, optical, vibrational, chemical, and weather monitoring) and other devices that commonly used batteries. For example, a solar concentrator may be placed on a surface of a vehicle, e.g., a car, recreational vehicle, golf cart, etc., to provide power to one or more battery storage devices used to provide starting, primary power or accessory power, e.g., power for operating air conditioning units, heating units, stoves, etc. in a recreational vehicle.

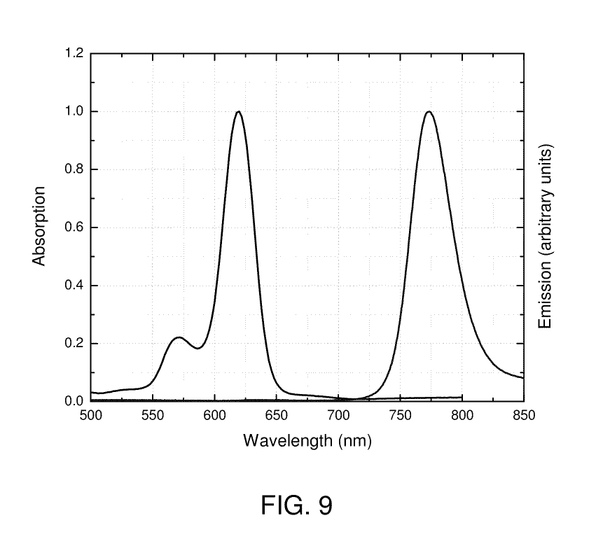

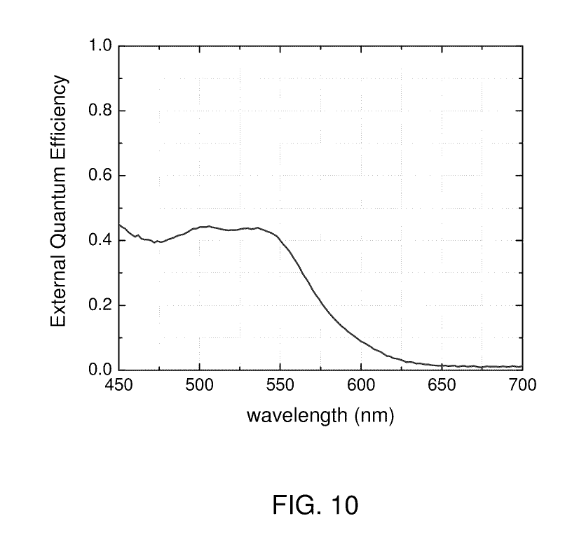

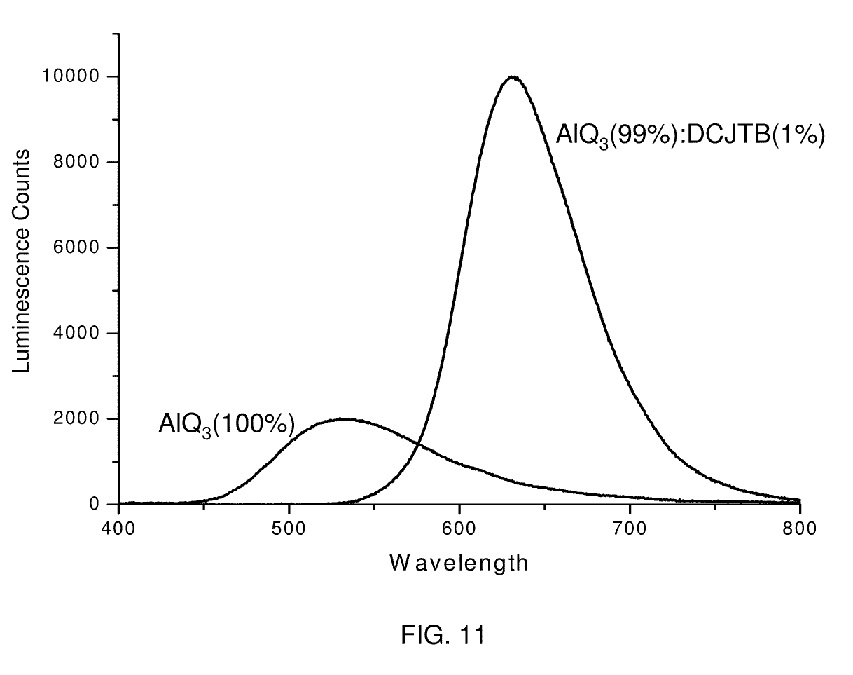

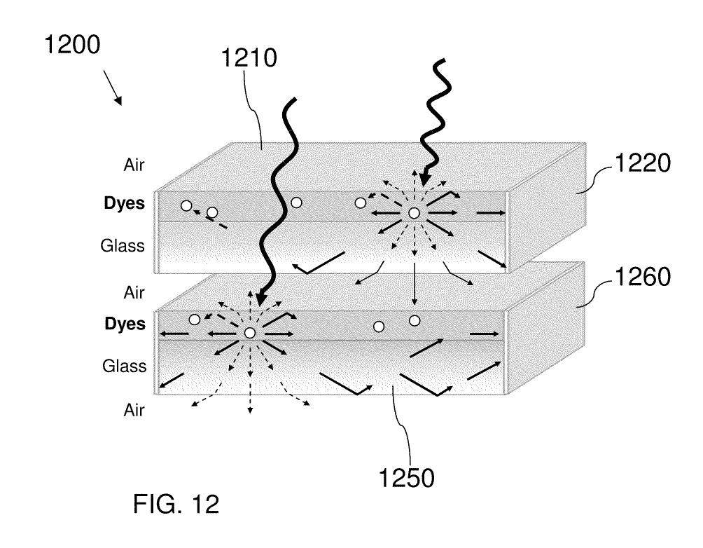

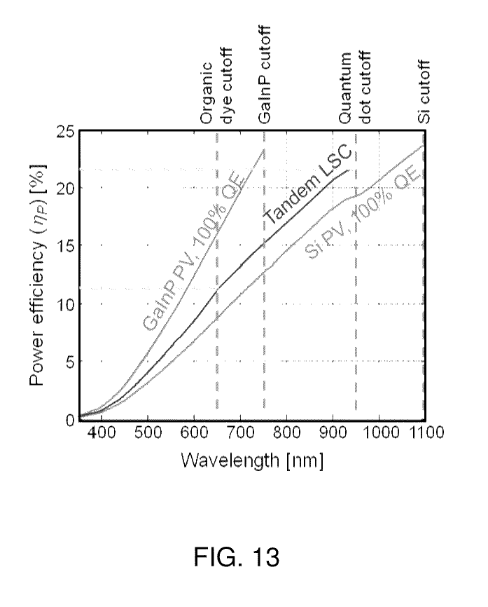

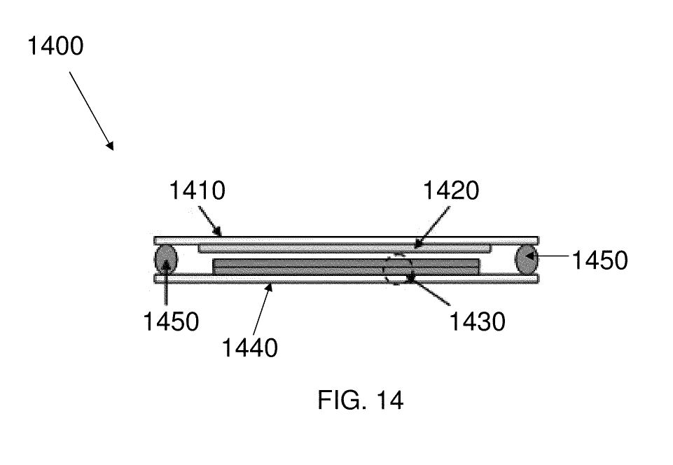

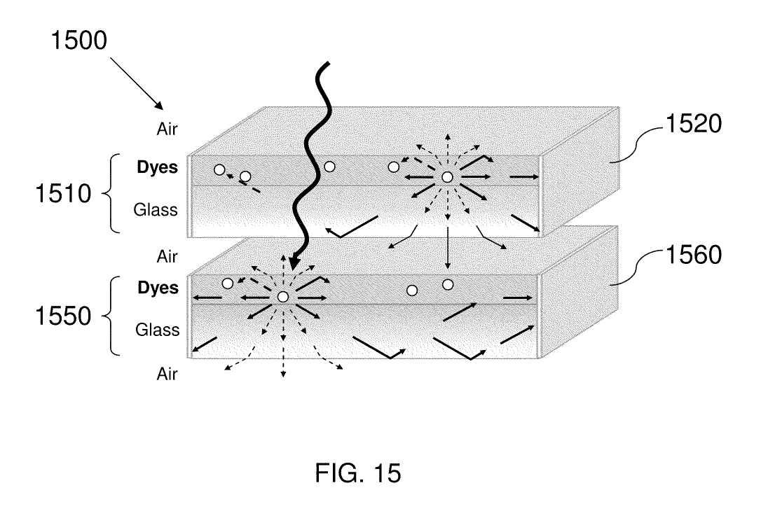

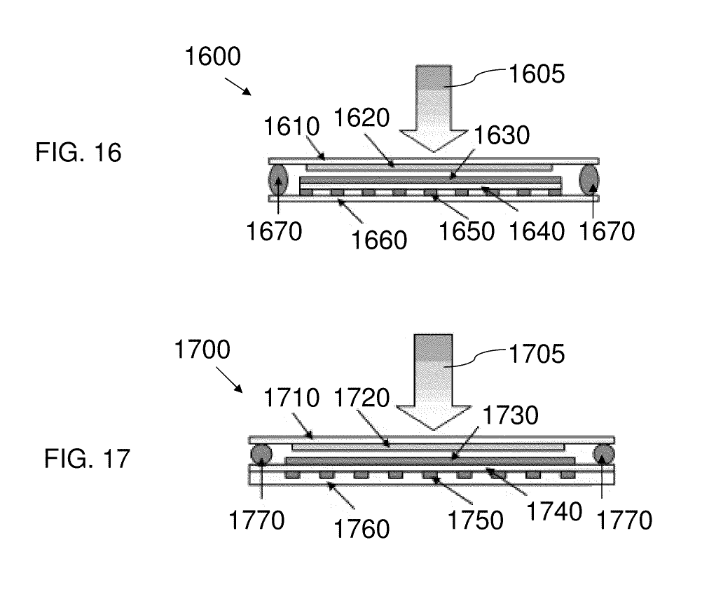

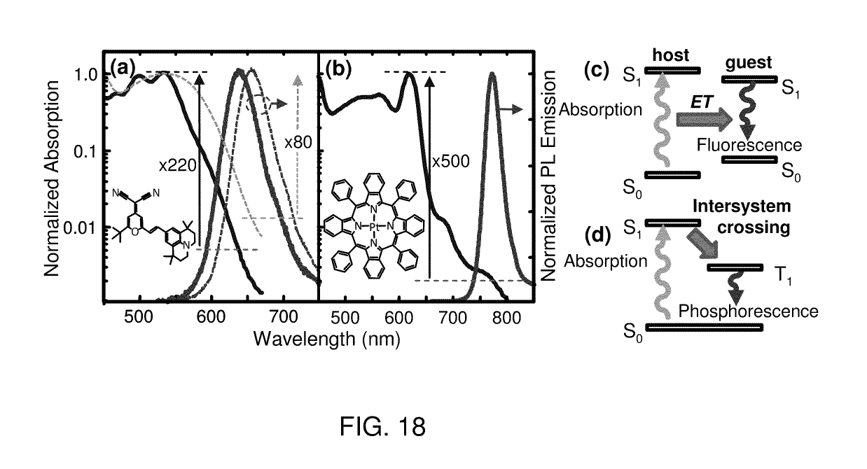

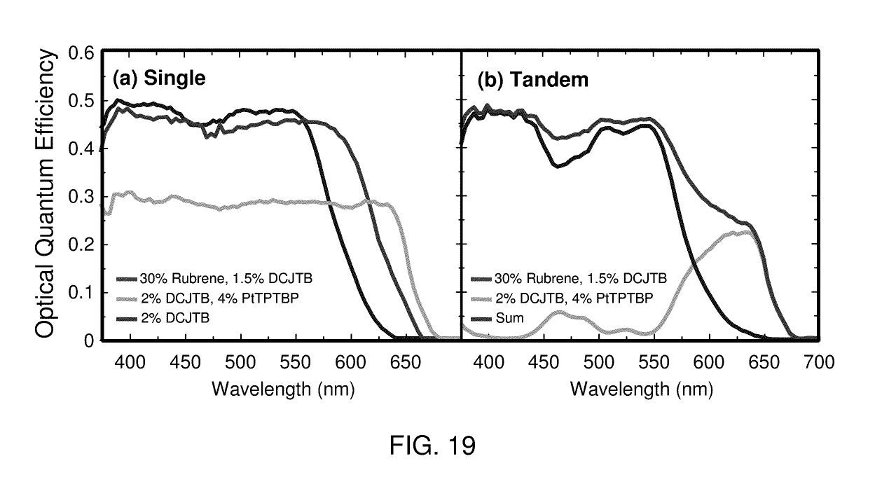

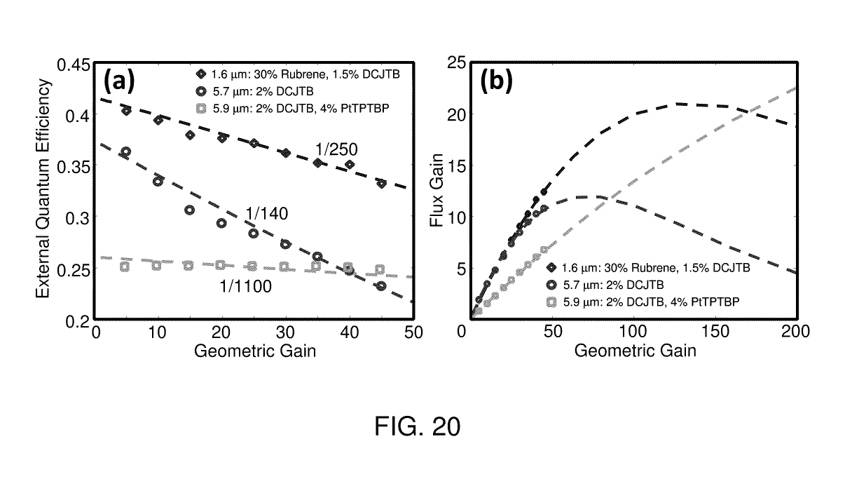

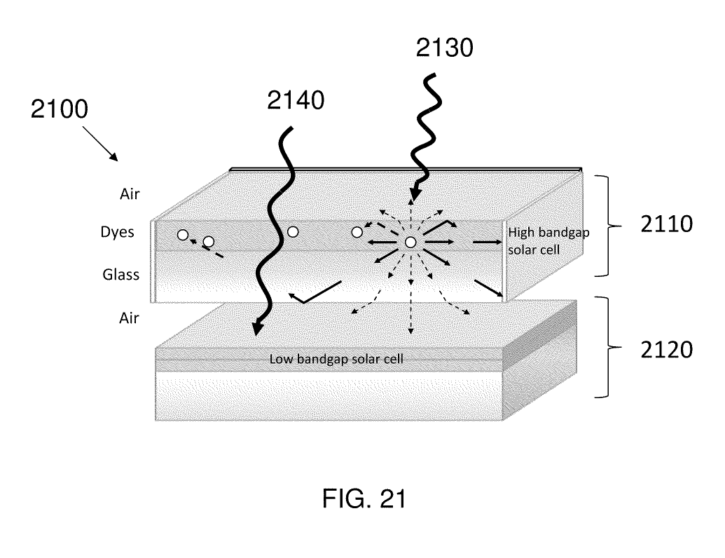

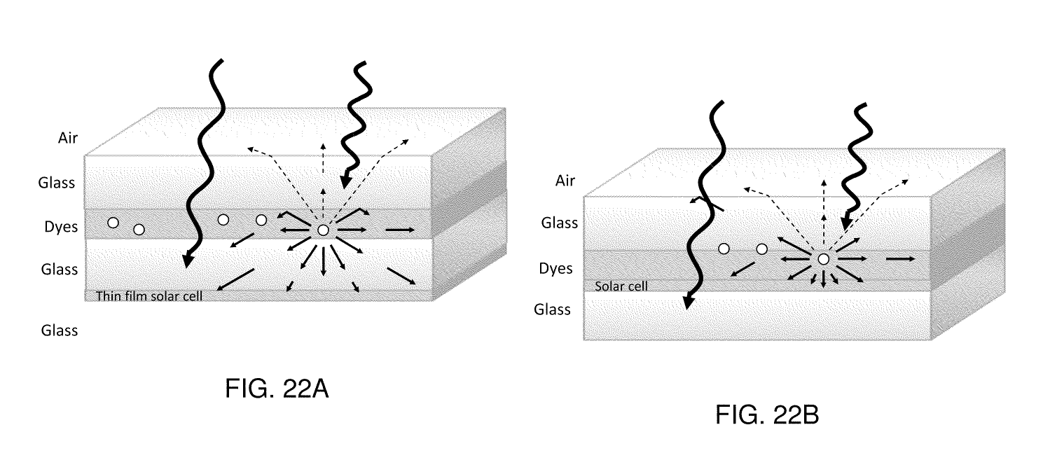

Two illustrative configurations of portable devices that are coupled to a solar concentrator are shown in FIGS. 9A and 9B. The dimensions in FIGS. 9A and 9B are arbitrary and no size or relative size should be implied or inferred. Referring to FIG. 9A, a portable device 910 is electrically coupled to a LSC/PV cell assembly 920 though interconnect 930. The LSC/PV cell assembly 920 is separate from the portable device 910, and current is supplied to the portable device 910 through the interconnect 920. The LSC of the LSC/PV assembly 920 may be any of those described herein, for example, those that include one or more chromophores, porphyrin compounds, organometallic compound, chromophore assemblies, an anti-Stokes material or combinations thereof. In certain examples, at least one of the chromophores of the LSC is tuned. Similarly, the PV cell of the LSC/PV cell assembly 920 may be any PV cell including the thin film PV cells described herein. In addition, the LSC/PV cell assembly may include more than one PV cell as described herein with respect to embodiments that include two or more PV cells, e.g., two or more PV cells having different efficiencies. Referring to FIG. 9B, an LSC/PV cell assembly 970 is shown as in the housing 960 of a portable device 950. The LSC/PV assembly 970 may be positioned along one or more surfaces that would receive incident light during operation or storage of the portable device. For example, the LSC/PV assembly 970 may be positioned on an upper surface of a mobile phone facing away from a user such that during use of the mobile phone, incident sunlight or ambient light may be captured by the LSC/PV cell assembly 970 to charge the mobile phone battery.

In embodiments where a LSC/PV cell assembly is used with a mobile device other suitable component, such as voltage converters, amplifiers, conditioners and the like may be used to provide a desired voltage output, waveform, intensity and the like. Such devices are conventionally known in the art and will be readily selected for use by the person of ordinary skill in the art, given the benefit of this disclosure.

In one embodiment, an LSC may be used for indoor light harvesting. For example, electronic shelf labels may include an LSC/PV cell assembly that can be electronically coupled to sensors, computers and the like. The electronic shelf label (ESL) may harvest light from indoor light sources, e.g., fluorescent bulbs, halogen bulbs, incandescent bulbs, light-emitting diodes, etc. used to provide ambient lighting in a room. The ESL may be electrically coupled to a device by placement on a shelf or by placement in the housing of the device. Irrespective of where the ESL is placed, the ESL desirably can receive incident light from the overhead light sources and convert that light to a current, which may be provided to the sensor, computer or other electronic device. In one embodiment, an LSC/PV assembly used in concert with a charge controller and energy storage device (i.e. battery or electronic capacitor) can be used to provide energy as the ESL requires.

When introducing elements of the aspects, embodiments and examples disclosed herein, the articles “a, “an,” “the” and “said” are intended to mean that there are one or more of the elements. The terms “comprising,” “including” and “having” are intended to be open-ended and mean that there may be additional elements other than the listed elements. It will be recognized by the person of ordinary skill in the art, given the benefit of this disclosure, that various components of the examples can be interchanged or substituted with various components in other examples.

Although certain aspects, examples and embodiments have been described above, it will be recognized by the person of ordinary skill in the art, given the benefit of this disclosure, that additions, substitutions, modifications, and alterations of the disclosed illustrative aspects, examples and embodiments are possible.

### EXAMPLES

### Example 1

### Dye Alignment in a Homeotropic Polymerizable Liquid Crystal Mixture

Vertically aligned and isotropic dyes were incorporated into scaffolds of a homeotropic polymerizable liquid crystal mixture or PMMA. The substrate employed was a 1-mm-thick glass with a refractive index, n=1.7 (SF10, Schott). Glass substrates were cut with a dicing saw to the desired dimensions. The geometric gain, G, of an LSC is defined as the ratio of the face area versus edge area. When solar cells are attached to each edge of a square collector, G=L/(4t), where L is the length of the LSC and t is the thickness. The glass substrates were cut to squares of 2×2 cm. The glass substrates were thoroughly cleaned with a detergent solution, DI water, and solvents.

The polymerizable homeotropic liquid crystal host used in this example was UCL018 (Dai Nippon Printing Co. Ltd.). This mixture includes a polymerizable nematic liquid crystal, homeotropic dopant molecules, and a photo-initiator. The dye molecule used in this example was Coumarin 6. In a vial, UCL018 (40%) was added to Coumarin 6 (0.40% total weight ˜1% solid weight content). FC-4430 (Novec™, 3M) was used as a surfactant (0.40%) and taken from a pre-prepared solution of 5% FC-4430 dissolved in toluene. To these substances, toluene was added (59.2%) and gently stirred. All percentages of the separate components are given relative to the total weight of the mixture. When the components were well dissolved (after being stored for approximately an hour in the dark at room temperature) the solution was filtered and spin-cast on the glass substrates. The spin-speed was adjusted to yield a peak-absorption of around 40% (optimized for specific experiments) (a typical spin-cast recipe uses an acceleration of 500 rpm/sec and a spin speed of 1250 rpm for a duration of 15 seconds). Directly after spinning, the samples were placed for 1 minute on a hotplate at 50° C. in still air. Subsequently, the samples were cooled to room temperature for 1 minute before being placed under a UV lamp (365 nm) for 2 minutes to cure.

Isotropic LSCs used PMMA (Sigma Aldrich) as a host matrix. In a vial, PMMA and toluene were added to a concentration of 150 mg/mL. The vials were heated (at 70° C.) and stirred to dissolve the PMMA. Coumarin 6 was added to obtain a concentration of 1.5 mg per mL of toluene (equal to a 1% solid weight content). After all components were well dissolved the solution was filtered and spin-cast on a clean glass substrate. The spin-speed was adjusted to obtain the desired peak-absorption within the sample. All thin film absorption measurements were obtained using an Aquila spectrophotometer at 30° incidence.

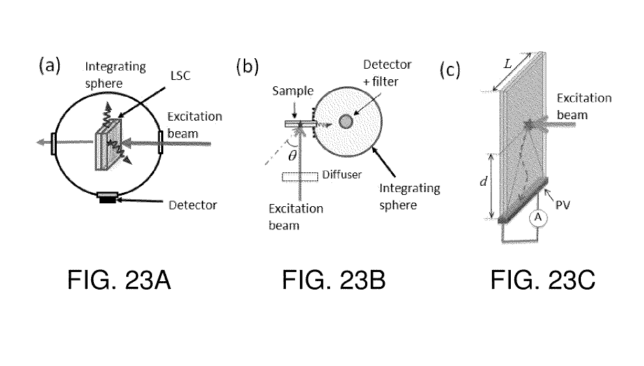

The trapping efficiency of conventional, isotropic LSCs and vertically-aligned LSCs was measured with the use of an integrating sphere (see FIG. 23a regarding the set-up). The samples were placed in the center of the sphere and excited by a monochromatic beam incident normal to the face of the samples. The beam was created by coupling a 150 W Xenon lamp into a monochromator and chopping it at 73 Hz. The photoluminescence of the LSCs was detected through a photo-detector mounted on the integrating sphere. The trapping efficiency was given by the ratio between the number of photons emitted from the edges of the LSC to the total number of photons that were emitted from both the face and the edge of the LSC. The face and edge emission were differentiated by selectively blocking the edge emission with a black marker. A correction for the difference in responsiveness of the integrating sphere and the photo-detector for clear edged and black edged samples was incorporated. The blackening with a black marker was tested to block over 98% of the transmission and internal reflections. The angular dependence of the absorption within isotropic and homeotropic (vertically aligned) LSCs was obtained from the edge emission as a function of the angle of the incident light beam. The fraction of photons emitted from the edge of the LSC were directly proportional to the number of photons absorbed within the waveguide and was a good measure of the performance of the LSC overall. This also allowed probing of the angular distribution of excited dyes within the LSC, which, for the isotropic LSCs, depended on the angle of the incident light. Increasing the incident angle will increase the number of excited vertical dipoles and result in an enhancement in the trapping efficiency. A schematic representation of the set-up used to test the angular dependence of the LSC performance is presented in FIG. 23b. One of the edges of the LSC was placed into the opening of an integrating sphere, while the other three edges of the glass were blackened out to prevent indirect radiation reaching the edge inserted into the sphere. The LSC was excited in the center of the waveguide with a λ=408 nm laser, whose power was monitored over time with the use of a beam-splitter and a second photo-detector. The remainder of the opening in the sphere was blocked and a spectral filter was used to prevent scattered laser light from reaching the photo-detector that had been mounted directly onto the sphere.

Holographic diffusers were obtained from Edmund Optics with ˜90% transmission efficiency under varying diffusive strengths. The diffusive strength (10°, 30° and 60° for the holographic diffusers used in this example) was the maximum angle to which at least 0.1% of the light is scattered given a collimated beam incident normal to the surface. The holographic diffuser was placed at a distance of 1 mm in front of the LSC (see FIG. 23b) and the laser beam was positioned to be incident normal to the diffuser surface.

The external quantum efficiency of an LSC, the ratio of electrons out to photons in, was measured using two GaAs solar cells from Spectrolab, each with an external quantum efficiency of ˜85% and cut into 3.8 cm×0.34 cm strips. The cells were connected in series, and attached to one of the short edges of the LSC with index matching fluid (Norland Products). The other 3 edges were blackened out with a black marker to prevent indirect luminescence from reaching the solar cell. The absorption within the films peaked at 42% for both the isotropic and homeotropic LSCs. FIG. 23c presents a schematic of the EQE-set-up. Concentration factor-dependent measurements were obtained by directing an excitation beam perpendicular to the LSC to create an excitation spot of ˜1 mm², while the distance, d, between the spot and the solar cell was varied. This technique simulated the performance of LSCs at different geometric gains and provided a lower bound for the performance since the average path-length was slightly longer than a uniformly illuminated LSC.

Results were compared to simulations using a Monte Carlo ray tracing model, extended to consider dye molecules with arbitrary orientations. The LSC components are modeled by their experimentally measured spectral absorption coefficients, photoluminescence spectra, photoluminescence quantum efficiency, and refractive indices. For example, the experimentally determined absorption and emission spectra of Coumarin 6 were used in this example along with the glass waveguide is modeled by SF10 parameters. The refractive index of the organic film was simulated as n_{S}=1.5 for the PMMA film and n_{S}=1.6 for the UCL018 film. The PL efficiency of Coumarin 6 was η_{PL}=78% and the EQE of the solar cell combined with the in-coupling was simulated to be 85%. The thickness of the PMMA and UCL018 films were adjusted to result in a absorption of 42% in the films, identical to experimental conditions. To match our experimental procedures, the input light was defined monochromatically at normal incidence for both s and p polarizations. For these simulations an input photon count of 30,000 was used that resulted in uncertainties of less than +/−0.5%.

EQE was simulated as a function of G for two different experimental configurations. The first configuration simulated the spot excitation technique and calculated the number of photons coupled to one of the edges as a function of the distance between that edge and the spot excitation. The correction factor presented above esd then used to account for the different angle subtended by the solar cell at each spot distance, and multiplying by the EQE of the solar cell attached to the edge yields the EQE of the LSC. The second configuration simulated EQE versus G for a uniformly illuminated LSC. The fraction of photons coupled to the four edges was multiplied by the EQE of the GaAs solar cell to obtain the EQE of the LSC.

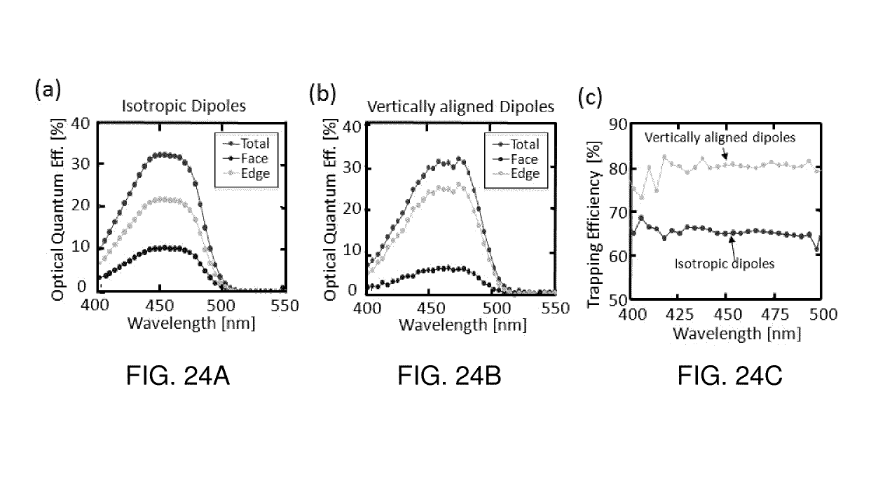

FIGS. 24a and 24b summarize the trapping efficiency for isotropic and vertically-aligned LSCs, respectively. The total absorption within both samples was 40%. One can observe a clear enhancement of the edge emission for the vertically aligned LSC over the isotropic LSC. To allow for a more quantitative assessment of the enhancement in edge emission, FIG. 4c presents the trapping efficiency for both the isotropic and the homeotropic LSCs. The trapping efficiency of the vertically aligned LSC was measured to be 81%, while the isotropic dye system results in a trapping efficiency of 66%. To the best of our knowledge, the vertically-aligned device exhibits the highest measured LSC trapping efficiency to date, although we note that the trapping efficiency of LSCs with dielectric mirrors has not been explicitly reported. Comparing these measured trapping efficiencies to theoretical predictions for ηₜᵣₐₚ, however, shows that the measured trapping efficiency of the vertically aligned and the isotropic LSC was lower than theoretically predicted. As discussed in the results below, this phenomenon is due, at least in part, to imperfect vertical alignment.

Next, optical absorption as a function of the incident angle of the excitation beam for vertically aligned LSCs and isotropic LSCs was measured. Increasing the coupling of radiation into the waveguide by aligning the transition dipole moment of the dyes perpendicular of the waveguide was expected to come at the expense of a reduced capability to absorb perpendicularly incident radiation.

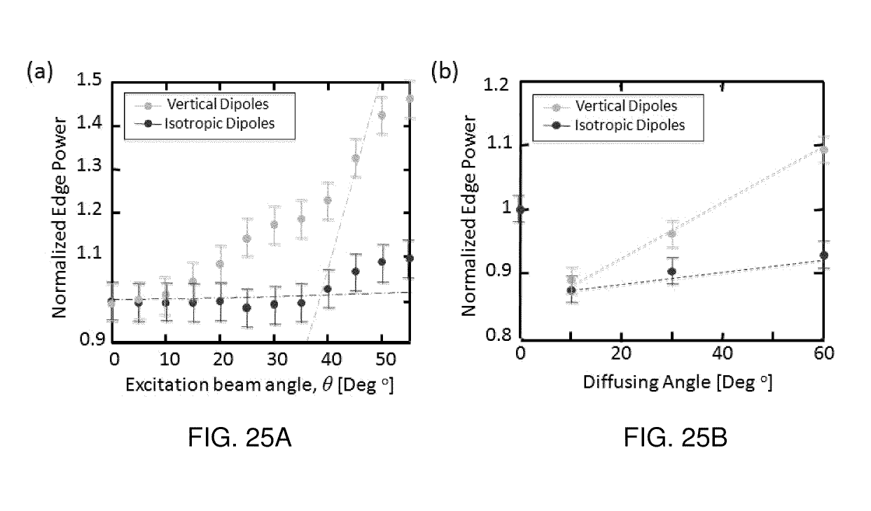

FIG. 25a presents the power emitted from the edge of the vertically aligned LSC and the isotropic LSC as a function of incidence angle, θ. The measured power was normalized to the edge emission at normal incidence. The expected increase in pump absorption at higher incidence resulting from the increased path length in the film was corrected for. The product at was determined from the absorption at normal incidence. The change in reflection off the face of the sample with increasing incident angle was calculated to be ˜2% and thus, was neglected. The performance of the isotropic sample was approximately constant with excitation angle, while the performance of the homeotropically aligned LSC increases monotonically. This was consistent with an increased ability of the vertically aligned dipoles to absorb light at higher angles, whereas the trapping efficiency of isotropic dipoles was only weakly dependent on the incident angle of the excitation light. The trapping efficiency was constant over all excitation angles for an LSC employing perfectly aligned vertical dipoles. An increase in edge emission would therefore follow the sin²θ_{INT} behavior of the absorption in the film. The theoretical prediction of the edge power to the measured edge power at 45° was normalized. The fact that the absorption of the vertically aligned LSC deviates from the behavior of a perfectly aligned homeotropic system may suggest that the actual alignment in the film was not ideal, partly explaining the lower value for the measured trapping efficiency in comparison to the predicted theoretical models.

To alleviate the weak absorption of homeotropically aligned LSCs under perpendicularly-incident light, external holographic diffusers were employed. The edge power of the LSC was monitored as a function of diffuser strength and is illustrated in FIG. 25b. The edge power was normalized to the edge power measured without the presence of the diffuser. The initial drop in edge-power at a diffuser strength of 10° resulted from the non-unity transmission efficiency of the diffuser. The vertically aligned, homeotropic LSC showed a clear improvement with increasing diffuser strength. The edge emission for the system that included the 60° diffuser was 10% better than the system without diffuser, and 20% better than the LSC result for the 10° diffuser. The isotropic LSC did not show an overall enhancement in performance due to the presence of the diffusers.

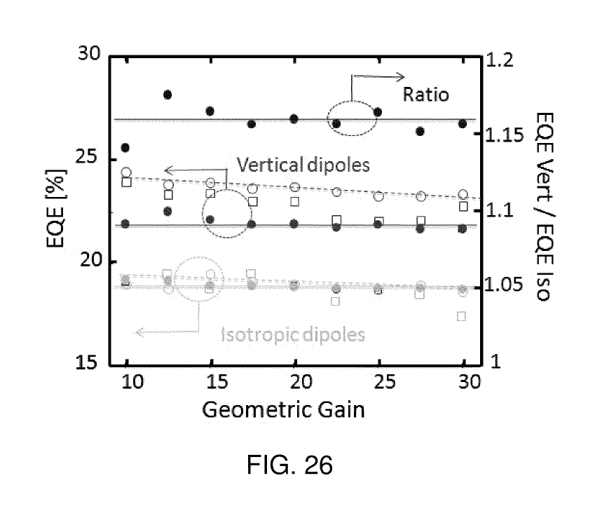

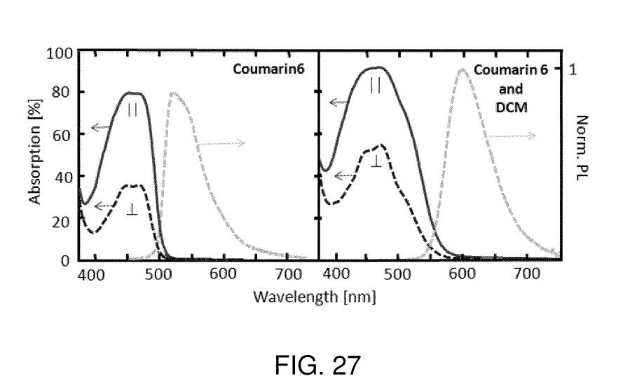

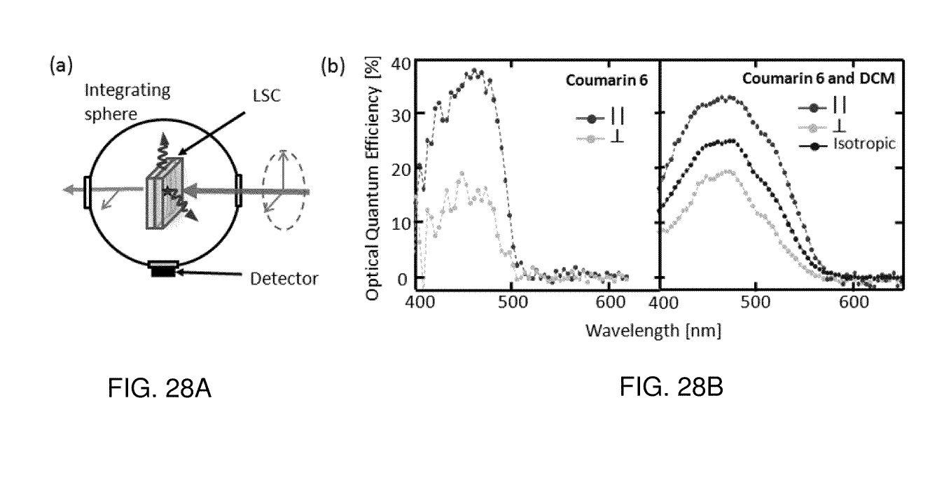

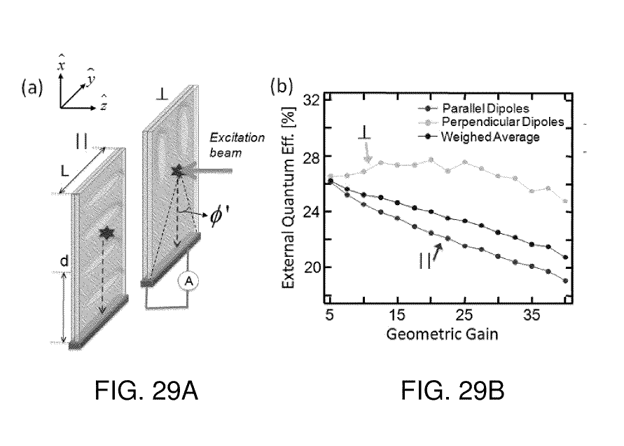

In FIG. 26, the external quantum efficiency for vertically-aligned and isotropic LSCs as a function of G was plotted. Consistent with an enhanced trapping efficiency of the homeotropic, vertically aligned LSCs, their performance was approximately 16% better than the isotropic LSCs for all measured concentration factors. The performance of the isotropic and homeotropic LSCs as a function of concentration factor was also simulated. To test the accuracy of the spot excitation-technique, both spot-illuminated waveguides (open squares) and uniformly illuminated waveguides (open circles) of various sizes were simulated. The Monte Carlo simulations closely resembled the experimentally obtained results demonstrating that the spot illumination technique accurately represented the concentration dependence of quantum efficiency, at least for these LSC samples.

### Example 2

Linear Polarized Luminescent Solar Concentrator (LP-LSC):A LP-LSC was created on a 1 mm-thick glass substrate with a refractive index, n=1.7 (SF10, Schott). The glass substrates were cut with a dicing saw to obtain the desired dimension. For measurements of optical quantum efficiency (the fraction of photons coupled to the edges of the LSC), the glass substrates are cut to squares of 2×2 cm, while for measurements of the external quantum efficiency (the fraction of incident photons converted to current in solar cells) the substrates are cut to a substrate size of 7.6×9.5 cm. The glass is then thoroughly cleaned with a detergent solution, DI water and solvents.

To create the alignment layer, a polyimide acid is diluted to a ratio of 1:1 with Solvent 25 (Nissan Chemical Industries, LTD), and spincast on the clean substrates in air with a ramp of 1000 rpm/sec and a spin speed of 2500 rpm for 30 s. The samples are then based on a hotplate in still air for 10 min at 80° C. and 60 min are 180° C. The coated samples were hand-rubbed with a velvet cloth to introduce alignment in the liquid crystal layer.

The polymerizable nematic liquid crystal host chosen for in this study is Paliocolor 242 (BASF) as discussed below. The dyes used for the experiments are Coumarin 6 and DCM (Sigma Aldrich) as discussed below. These dyes were selected because of their relatively high dichroic ratio and their high photoluminescence efficiency. Coumarin 6 also possesses a large Stokes shift, making this dye well suited for LSC purposes.

In the following example all percentages of the components are given in weights relative to the total weight of the mixture. In a vial, a solution was prepared that contained Paliocolor (30%), Coumarin 6 (0.30%) or both DCM and Coumarin 6 (both at 0.30%). To these powders, toluene was added (68.95%) and gently stirred. As a surfactant BYK-361 (BYK-Chemie) was used (0.15%), which was taken from a pre-prepared solution of 5% BYK-361 dissolved in toluene. Lastly, Irgacure 184 (0.60%, Ciba Chemicals) was added as a photo initiator. When the components were well dissolved the solution is spin-cast on the pre-rubbed substrates. The samples were dried for 3 minutes at room temperature in still air, after which they are placed for 4 minutes on a hotplate at 80° C. (also in still air). The samples were cooled to room temperature for 1 minute before being placed under a UV lamp (365 nm) for 3 minutes to cure. This spin speed was adopted to yield a film thickness that resulted in a peak absorption of 78% for light that was polarized parallel to the rubbing direction for the Coumarin 6 LP-LSCs. The film-thickness was estimated to be 1.1 microns thick through optical modeling. All thin film absorption measurements were obtained using an Aquila spectrophotometer.

The resulting absorption and photoluminescence spectra of the above example are provided in FIG. 23. Absorption was measured in both parallel and perpendicular to the rubbing direction. From these measurements the order parameter, S, defined by S=(A_{∥}−A_{⊥})/(A_{∥}+2A_{⊥}) was determined. Here, A_{∥} is defined as the absorbance of the sample for incident light polarized parallel to the rubbing direction, and A_{⊥} is the absorbance for light polarized perpendicular to the rubbing direction. The samples that contained solely Coumarin 6 are found to have an order parameter of 0.52, while the samples that contained both Coumarin 6 (C6) and DCM are measured to have an order parameter of 0.45. The absorption of the C6-DCM sample is extended relative to the C6 sample but still exhibits dichroism.

The photoluminescence (PL) spectra of the C6 and DCM-C6 sample were also plotted in FIG. 23. These spectra were obtained from the face of the device under excitation by a λ=408 nm laser. The photoluminescence efficiency of the C6 samples was measured with an integrating sphere. The luminescence of the C6-DCM sample originates from the DCM dyes, confirming that energy is effectively funneled to the DCM molecules through Förster transfer. The PL efficiency of the C6-DCM samples was measured to be 60%. The similarity between literature and measured PL efficiencies suggests that the dyes are not quenched nor degraded during our device fabrication procedure.

The optical quantum efficiency, OQE, defined as the fraction of photons coupled to the edges of the LSC. It is characterized within an integrating sphere (see FIG. 24 for a schematic representation of the set-up). The edge and facial LSC emission are differentiated by selectively blocking the edge emission with a black marker (which has been tested to block above 98% of the internal reflection). The OQE was determined for light that was polarized parallel and perpendicular to the rubbing direction, i.e. polarized along the long or short axis of the dye molecules. These spectrally resolved measurements use a 150 W Xenon lamp that was coupled into a monochromator and chopped at 73 Hz. The photoluminescence for the OQE measurements was detected by a Si photodetector mounted directly on the integrating sphere and which in turn was connected to a lock-in amplifier.

The spectrally resolved OQE of the C6 and the C6-DCM samples is also shown in FIG. 24. The samples used for these measurements were identical to the samples used for the absorption measurements presented in FIG. 23. The C6 sample has a peak OQE of 38% for light that was polarized parallel to the rubbing direction. This efficiency number was the product of the peak absorption of 78% for this polarization (see FIG. 23), a PL efficiency of 78% and a trapping efficiency of 62%. The trapping efficiency was determined within the integrating sphere. For light that was polarized perpendicular to the rubbing direction the maximum OQE was measured to be 17%. This lower number resulted from the lower absorption (33%) within the sample for this polarization (See FIG. 23). The sample that contains both C6 and DCM has a peak OQE of 34% for light that was polarized parallel to the rubbing direction. This number was the product of an absorption of 93% (FIG. 23—right panel), a measured photoluminescent efficiency of 60%, and a trapping efficiency of 62%. The perpendicular polarization resulted in a peak OQE of 18%. When unpolarized light was used as an excitation source the OQE was measured to be 25% for the parallel and perpendicular polarized excitation sources.

The external quantum efficiency (EQE) as a function of geometric gain, G, for the LP-LSCs is presented in FIG. 25. The results obtained for dipoles that were aligned parallel to the solar cell are depicted as a red dotted line, while the perpendicular dipoles are presented as green dots. The EQE is measured at λ=465 nm.

It was observed that the parallel dipoles have a more pronounced roll-off in efficiency with increasing concentration factor, resulting from stronger overlap between the emissive and absorptive dipoles along the path that the photons have to travel towards the solar cell. A uniformly illuminated LP-LSC will have a performance that is the average of the two curves weighted by f_{□} and f_{⊥}, each evaluated at φ=45° (blue line in FIG. 5). The theory yields a ratio of emission to the edges parallel and perpendicular to the dipoles of 2.4:1, respectively. Due to stronger self-absorption for light coupled to the parallel edges, the measured ratio was 2:1.

What is claimed is:

1. A solar concentrator comprising a substrate and at least first and second closely spaced chromophores disposed on or in the substrate in a manner to receive at least some optical radiation, the first chromophore effective to absorb at least one wavelength of at least some of the optical radiation and further effective to transfer at least some energy by Förster energy transfer to the second chromophore, the second chromophore effective to emit at least some of the transferred energy at a wavelength that is red-shifted from the wavelength absorbed by the first chromophore, in which second chromophore is tuned to provide light emission in substantially one direction.

2. The solar concentrator of claim 1, in which the substrate is a glass comprising a refractive index of at least 1.7.

3. The solar concentrator of claim 1, in which the second chromophore is tuned by trapping the second chromophore in a matrix or by disposing the second chromophore in a viscous medium.

4. The solar concentrator of claim 1, further comprising an effective amount of a red-shifting agent to shift an emission wavelength range of the second chromophore to a higher wavelength range.

5. The solar concentrator of claim 1, in which the second chromophore is tuned using an electric field applied to the solar concentrator.

6. The solar concentrator of claim 1, in which the second chromophore is selected from the group consisting of an organometallic compound, a porphyrin compound, a chromophore assembly and a chromophore complex.

7. The solar concentrator of claim 1, further comprising at least one wavelength selective mirror disposed on the substrate, the wavelength selective mirror configured to transmit incident light in a first wavelength range and to reflect incident light in a second wavelength range.

8. The solar concentrator of claim 1, in which the first and second chromophores are both tuned by trapping them in a matrix, wherein at least one of the first and second chromophores is covalently bound to the matrix.

9. The solar concentrator of claim 1, further comprising a first photovoltaic cell optically coupled to the solar concentrator.

10. The solar concentrator of claim 9, further comprising a second photovoltaic cell optically coupled to the solar concentrator, wherein the efficiency of the first and second photovoltaic cells are different.

11.-70. (canceled)

71. A solar concentrator comprising:
a substrate; and
a composition disposed on or in the substrate in a manner to absorb at least some optical radiation, the composition comprising at least one tuned chromophore assembly effective to provide emission in substantially one direction.

72. The solar concentrator of claim 71, in which the substrate is a glass comprising a refractive index of at least 1.7.

73. The solar concentrator of claim 71, in which the tuned chromophore assembly is selected from the group consisting of a chlorin, a phycobilosome, a porphyrin, a cyanine dye, perylene bisimide dye, a J-aggregate and an H-aggregate.

74. The solar concentrator of claim 71, in which the composition further comprises a red-shifting agent.

75. The solar concentrator of claim 71, in which the composition further comprises a plurality of absorbing chromophores and one terminal chromophore.

76. The solar concentrator of claim 71, in which the tuned chromophore assembly is tuned using an electric field, by trapping it in a matrix or by disposing it in a viscous medium.

77. The solar concentrator of claim 71, further comprising at least one wavelength selective mirror disposed on the substrate, the wavelength selective mirror configured to transmit incident light in a first wavelength range and to reflect incident light in a second wavelength range.

78. The solar concentrator of claim 71, further comprising a matrix to which the chromophore assembly is covalently bound.

79. The solar concentrator of claim 71, further comprising a first photovoltaic cell optically coupled to the solar concentrator.

80. The solar concentrator of claim 79, further comprising a second photovoltaic cell optically coupled to the solar concentrator, wherein the efficiency of the first and second photovoltaic cells are different.

81.-114. (canceled)

115. A tandem device comprising the solar concentrator of claim 1 coupled to a thin film photovoltaic cell, wherein the solar concentrator and the thin film photovoltaic cell are each selected to have different bandgaps.

116.-121. (canceled)

122. A tandem device comprising the solar concentrator of claim 71 coupled to a thin film photovoltaic cell, wherein the solar concentrator and the thin film photovoltaic cell are each selected to have different bandgaps.

123.-126. (canceled)

127. A device comprising the solar concentrator of claim 1 coupled to a portable electronic device.

128. The device of claim 127, in which the portable electronic device is selected from the group consisting of a digital audio player, a mobile phone, a personal digital assistant, a portable computer, an image sensor, a camera, and a mobile environmental sensor.

129.-138. (canceled)

139. A device comprising the solar concentrator of claim 71 coupled to a portable electronic device.

140. The device of claim 139, in which the portable electronic device is selected from the group consisting of a digital audio player, a mobile phone, a personal digital assistant, a portable computer, an image sensor, a camera, and a mobile environmental sensor.

141.-148. (canceled)
